(19) United States
(12) Patent Application Publication
(10) Pub. No.: US 2026/0007052 A1
(43) Pub. Date: Jan. 1, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Jun Hee LEE, Yongin-si (KR); Beohm Rock CHOI, Yongin-si (KR); MINJUNG ANN, Yongin-si (KR); Hyun Duck CHO, Yongin-si (KR); YECHAN CHOI, Yongin-si (KR)

(21) Appl. No.: 19/232,990

(22) Filed: Jun. 10, 2025

(30) Foreign Application Priority Data
Jun. 26, 2024 (KR) 10-2024-0083576
Dec. 3, 2024 (KR) 10-2024-0177424

(51) Int. Cl. H10K 59/80; H10K 59/122

(52) U.S. Cl. CPC H10K 59/879; H10K 59/122

(57) ABSTRACT

A display device includes a substrate; transistors disposed on the substrate; first and second insulation layers sequentially disposed on the transistors; subpixels including first to third subpixels, each including a subpixel electrode disposed on the second insulation layer, a light emitting layer disposed on the subpixel electrode, and an opposite electrode disposed on the light emitting layer; a partition wall including lower openings defining light emitting areas of the subpixels; a light blocking layer including upper openings disposed on the partition wall and respectively overlapping the lower openings; and first to third color filters disposed in the upper openings. The first subpixels comprise a 1-1 subpixel and a 1-2 subpixel emitting light of a same color. The second insulation layer comprises a first area overlapping the 1-1 subpixel and a second area overlapping the 1-2 subpixel. A step is positioned between upper surfaces of the first and second areas.

### CROSS-REFERENCE TO RELATED APPLICATION

This application claims priority under 35 U.S.C. § 119 to Korean Patent Application No. 10-2024-0083576, filed on Jun. 26, 2024 in the Korean Intellectual Property Office (KIPO), and Korean Patent Application No 10-2024-0177424, filed on Dec. 3, 2024 in KIPO, the disclosures of which are incorporated by reference in their entireties herein.

### TECHNICAL FIELD

The present disclosure relates to a display device and an electronic device including the same.

### DISCUSSION OF RELATED ART

A display device is a device that displays images on a screen to a user. Examples of display devices include a liquid crystal display (LCD) and an organic light emitting diode (OLED) display. A display device may be applied to various types of electronic devices, such as portable phones, navigation devices, digital cameras, electronic books, portable game machines, or various terminals.

Recently, as the use of display devices has become more diverse, various designs are being attempted to increase the quality of the display device.

### SUMMARY

Embodiments are intended to provide a display device with increased display quality by increasing light efficiency and reducing indirect patterns caused by external light reflection and diffraction.

According to an embodiment of the present disclosure, a display device includes a substrate. A plurality of transistors is disposed on the substrate. A first insulation layer and a second insulation layer are sequentially disposed on the plurality of transistors. A plurality of subpixels includes first subpixels, second subpixels, and third subpixels. Each of the plurality of subpixels including a subpixel electrode disposed on the second insulation layer, a light emitting layer disposed on the subpixel electrode, and an opposite electrode disposed on the light emitting layer. A partition wall includes a plurality of lower openings defining light emitting areas of the plurality of subpixels. A light blocking layer includes a plurality of upper openings disposed on the partition wall and respectively overlapping the plurality of lower openings. A first color filter, a second color filter, and a third color filter are disposed in the plurality of upper openings, respectively. The first subpixels comprise a 1-1 subpixel and a 1-2 subpixel that emit light of a same color as each other. The second insulation layer comprises a first area overlapping the 1-1 subpixel and a second area overlapping the 1-2 subpixel. A step is positioned between an upper surface of the first area and an upper surface of the second area.

In an embodiment, light reflected from the 1-1 subpixel may have a phase difference with light reflected from the 1-2 subpixel, and the phase difference may be

$$\frac{m}{2} λ 1$$

in which m is an odd number.

In an embodiment, a height of the step may be

$$\frac{m}{2 n ( 1 + cos θ )} λ 1 ,$$

in which m is the odd number and n is a refractive index.

In an embodiment, the display device may include a first pattern disposed below the 1-2 subpixel and disposed between the first insulation layer and the second insulation layer, and a second pattern disposed below the 1-1 subpixel and disposed between the first insulation layer and the second insulation layer.

In an embodiment, the first insulation layer may include a first recess portion overlapping the second pattern, and at least a portion of the second pattern may be disposed in the first recess portion.

In an embodiment, a height of an upper surface of the first pattern with respect to an upper surface of the substrate may be greater than a height of an upper surface of the second pattern with respect to the upper surface of the substrate.

In an embodiment, a height of the step may be proportional to a depth of the first recess portion of the first insulation layer.

In an embodiment, a third insulation layer may be disposed on the second insulation layer.

In an embodiment, the third insulation layer may have a same thickness in an upper part of the first area and an upper part of the second area.

In an embodiment, the display device may further include a data conductive layer disposed on the first insulation layer, and a third pattern of the data conductive layer in a portion where the first insulation layer overlaps the second area.

In an embodiment, a thickness of the third pattern may be about 6800 Å.

In an embodiment, a height of the step may be in a range of about 250 nm to about 270 nm.

In an embodiment, a planarity of a planarization layer that include the first insulation layer and the second insulation layer overlapping the respective light emitting areas may be within 30 nm, and the planarity may be a difference between a smallest height and a largest height from a bottom surface of the planarization layer to a top surface of the planarization layer.

According to an embodiment of the present disclosure, a display device includes a substrate. A plurality of transistors is disposed on the substrate. A first insulation layer, a second insulation layer, and a third insulation layer are sequentially disposed on the plurality of transistors. A plurality of subpixels include first subpixels, second subpixels, and third subpixels. Each of the plurality of subpixels including a subpixel electrode disposed on the second insulation layer, a light emitting layer disposed on the subpixel electrode, and an opposite electrode disposed on the light emitting layer. A partition wall includes a plurality of lower openings defining light emitting areas of the plurality of subpixels. A light blocking layer includes a plurality of upper openings disposed on the partition wall and respectively overlapping the plurality of lower openings. A first color filter, a second color filter, and a third color filter are disposed in the plurality of upper openings, respectively. The first subpixels comprise a 1-1 subpixel and a 1-2 subpixel that emit light of a same color as each other. The second insulation layer comprises a first area overlapping the 1-1 subpixel and a second area overlapping the 1-2 subpixel. The third insulation layer comprises a third area overlapping the 1-1 subpixel and a fourth area overlapping the 1-2 subpixel. A step is positioned between an upper surface of the third area and an upper surface of the fourth area.

In an embodiment, light reflected from the 1-1 subpixel may have a phase difference with light reflected from the 1-2 subpixel.

In an embodiment, a fifth pattern may be disposed between the first insulation layer and the first area, and a fourth pattern may be disposed between the first insulation layer and the second area.

In an embodiment, a dummy pattern may be disposed between the second insulation layer and the fourth area.

In an embodiment, the phase difference may be

$$\frac{m}{2} λ 1$$

and a height of the step may be

$$\frac{m}{2 n ( 1 + cos θ )} λ 1$$

in which m is an odd number and n is a refractive index.

According to an embodiment of the present disclosure, an electronic device includes a cover window. A housing is combined with the cover window. A display device is disposed in a space defined by the cover window and the housing. The display device comprises a substrate. A plurality of transistors is disposed on the substrate. A first insulation layer and a second insulation layer are sequentially disposed on the plurality of transistors. A plurality of subpixels includes first subpixels, second subpixels, and third subpixels. Each of the plurality of subpixels includes a subpixel electrode disposed on the second insulation layer, a light emitting layer disposed on the subpixel electrode, and an opposite electrode disposed on the light emitting layer. A partition wall includes a plurality of lower openings defining light emitting areas of the plurality of subpixels. An encapsulation layer and a touch sensor layer are disposed on the opposite electrode. A light blocking layer includes a plurality of upper openings disposed on the touch sensor layer and respectively overlapping the plurality of lower openings. A first color filter, a second color filter, and a third color filter are disposed in the plurality of upper openings, respectively. The first subpixels comprise a 1-1 subpixel and a 1-2 subpixel that emit light of a same color as each other. The second insulation layer comprises a first area overlapping the 1-1 subpixel and a second area overlapping the 1-2 subpixel. A step is positioned between an upper surface of the first area and an upper surface of the second area. A polarizer is not disposed above the touch sensor layer.

In an embodiment, the electronic device may include a first pattern disposed below the 1-2 subpixel and disposed between the first insulation layer and the second insulation layer, and a second pattern disposed below the 1-1 subpixel and disposed between the first insulation layer and the second insulation layer.

According to embodiments, a display device in which the reflection diffraction phenomenon is reduced without degrading the optical characteristics when in a display state by reducing the double image by utilizing a structure capable of generating a phase difference can be provided.

### BRIEF DESCRIPTION OF THE DRAWINGS

FIG. 1A is a schematic perspective view of an electronic device according to an embodiment of the present disclosure.

FIG. 1B is a schematic perspective view of the electronic device according to an embodiment of the present disclosure.

FIG. 1C is a block diagram of an electronic device according to an embodiment of the present disclosure.

FIG. 1D are schematic diagrams of an electronic device 1 according to various embodiments of the present disclosure.

FIG. 1E is a schematic perspective view of a display device according to an embodiment of the present disclosure.

FIG. 2 shows a light emitting diode of the display device and a subpixel circuit connected to the light emitting diode according to an embodiment of the present disclosure.

FIG. 3 is a cross-sectional view that schematically illustrates a display device according to an embodiment of the present disclosure, and is a cross-sectional view of the display device of FIG. 1E, taken along the line I-I′.

FIG. 4 is a schematic cross-sectional view of a display device according to an embodiment of the present disclosure.

FIG. 5 is a schematic top plan view of the anti-reflection layer of the display device according to an embodiment of the present disclosure.

FIG. 6 is a top plan view of the pixel arrangement of a portion of the display device according to an embodiment of the present disclosure.

FIG. 7 is a schematic cross-sectional view of the display device according to an embodiment of the present disclosure.

FIG. 8 is a graph that shows a step of the planarization layer according to a pattern embedding depth of the display device according to an embodiment of the present disclosure.

FIGS. 9A-9E are images of the planarization layer according to the pattern embedding depth of the display device according to an embodiment of the present disclosure.

FIG. 10 is a schematic cross-sectional view of the display device according to an embodiment of the present disclosure.

FIG. 11 and FIG. 12 are top plan views of the conductive layer SD according to embodiments of the present disclosure.

FIG. 13 is a schematic cross-sectional view of the display device according to an embodiment of the present disclosure.

FIG. 14 is a graph that shows a step of the planarization layer according to a thickness of the dummy pattern of the display device according to an embodiment of the present disclosure.

FIGS. 15A, 15B, 15C and 15D are profile images of the planarization layer according to thicknesses of the dummy pattern according to embodiments of the present disclosure.

FIG. 16A and FIG. 16B are images showing peaks on the point diffusion function of light diffraction at a pixel according to embodiments of the present disclosure.

FIG. 17A and FIG. 17B are drawings illustrating the effects of destructive interference and constructive interference on the peak of the point diffusion function of light.

FIG. 18 and FIG. 19 provided to describe the principle of reducing the double image by using a phase difference.

FIG. 20 and FIG. 21 are tables that show a step of the planarization layer that can reduce the double image.

FIG. 22 is a top plan view of a part of the display device according to an embodiment of the present disclosure.

FIG. 23A is a double-image image of a display device according to the comparative example.

FIG. 23B is an image that shows the double image reduction effect of the display device according to an embodiment of the present disclosure.

### DETAILED DESCRIPTION OF EMBODIMENTS

Hereinafter, non-limiting embodiments of the present disclosure are described in detail with reference to the accompanying drawings. However, embodiments of the present disclosure be implemented in many different forms and is not limited to embodiments described herein.

To clearly explain the present disclosure, parts that are not related to the description are omitted, and the same reference symbols are used for identical or similar components throughout the specification.

In addition, the size and thickness of each component shown in the drawing may be arbitrarily illustrated for better understanding and ease of description, and the present disclosure is not necessarily limited to what is illustrated. In the drawings, the thickness of layers, films, panels, regions, etc., may be exaggerated for clarity. In addition, for better understanding and ease of description, the thickness of some layers and regions may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “above” or “on” the referenced part means being disposed above or below the referenced part, and does not necessarily mean being disposed “above” or “on” the opposite direction of gravity.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

The present disclosure concerns a display device that has increased light efficiency and image quality by reducing or preventing the occurrence of double images. The display device includes a step that provides a phase difference between light emitted by adjacent subpixels and disperses the positions where constructive interference of the reflected light occurs. The phase difference between a first light and a second light emitted by the adjacent subpixels, respectively, may be an odd multiple of half the wavelength of the incident light.

In some embodiments, the step may be formed by having a source electrode and a drain electrode embedded in a first insulation layer, by having a source electrode and a drain electrode disposed outside the light emitting area or by having a dummy pattern disposed between a second insulation layer and a third insulation layer. In the display device, a polarizer may not be disposed above the touch sensor layer.

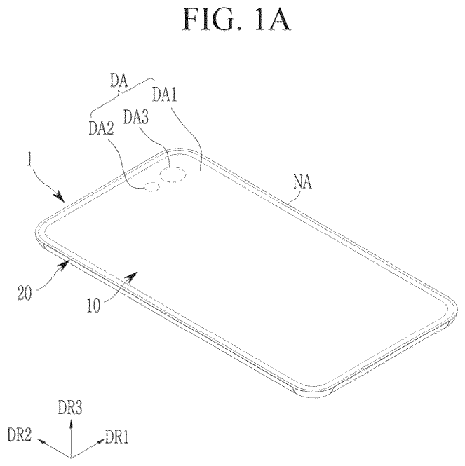

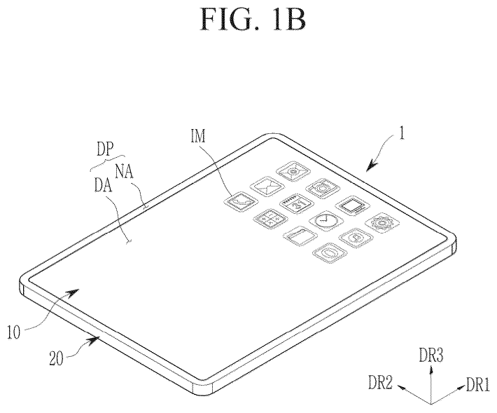

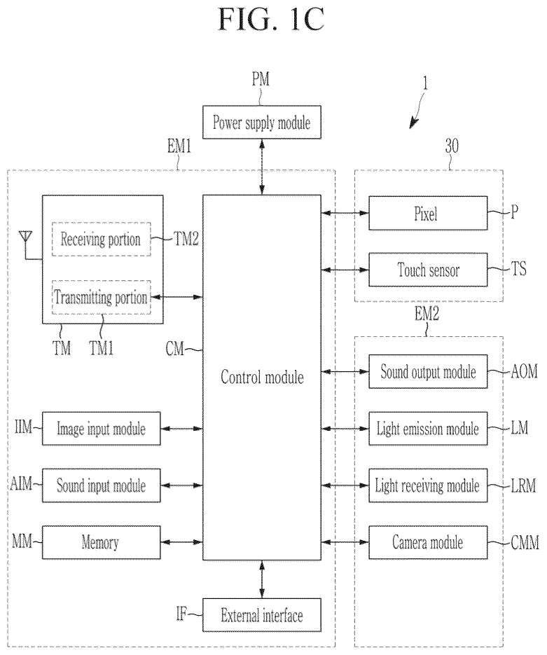

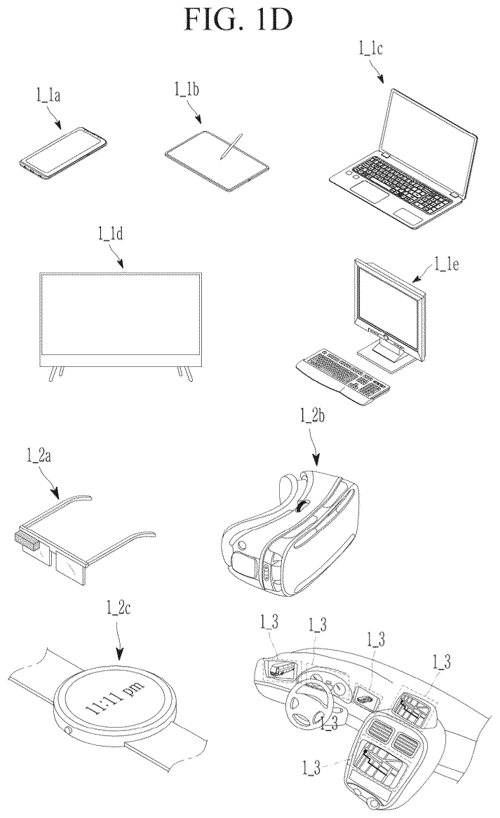

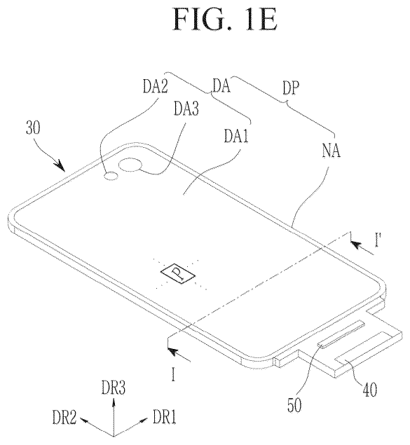

FIG. 1A and FIG. 1B are schematic perspective views of an electronic device according to an embodiment. FIG. 1C is a block diagram of an electronic device according to an embodiment. FIG. 1D are schematic diagrams of an electronic device 1 according to various embodiments. FIG. 1E is a schematic perspective view of a display device according to an embodiment.

Referring to FIG. 1A to FIG. 1C, an electronic device 1 may include a display screen that can display an image in a third direction DR3 that corresponds to a front direction on a plane defined by a first direction DR1 and second direction DR2. In an embodiment, the electronic device 1 may be a device of which a main function is to display images, such as a smart phone, a mobile phone, a tablet, a multimedia player, a game console, or a monitor. However, embodiments of the present disclosure are not necessarily limited thereto and the electronic device 1 may be various different small-sized, medium-sized or large-sized electronic devices.

The electronic device 1 may display an image IM towards the third direction DR3. The image IM may include at least one still image and/or a dynamic image. FIG. 1B illustrates a plurality of software application icons as an example of the image IM. However, embodiments of the present disclosure are not necessarily limited thereto.

The electronic device 1 may include a cover window 10, a housing 20, a display device 30, and the like.

The cover window 10 may include an insulation panel. For example, in an embodiment the cover window 10 may be composed of glass, plastic, or a combination thereof. A front of the cover window 10 may define a front of the electronic device 1. In the cover window 10, a region corresponding to the display screen may be optically transparent. The cover window 10 is disposed on the display device 30 and protects the display device 30 from an external impact and the like, and an image displayed by the display device 30 may be transmitted through the cover window 10. The cover window 10 may also be considered to be a component of the display device 30.

The housing 20 may be made of a material with relatively high rigidity. For example, in an embodiment the housing 20 may include glass, plastic, or a metal, or may include a plurality of frames and/or plates formed of a combination of glass, plastic, or a metal. The housing 20 may be combined with the cover window 10, and the combined housing 20 and cover window 10 may form the appearance of the electronic device 1 and provide an internal space of the electronic device 1. For example, the housing 20 may form back and side surfaces of the electronic device 1, and the cover window 10 may form the front surface of the electronic device 1. A display device 30 and the like may be disposed in the internal space defined by the cover window 10 and the housing 20, and the display device 30 and the like may be protected from the external environment by the cover window 10 and the housing 20.

The display device 30 may display an image, and may provide a display screen of the electronic device 1. In an embodiment, the display device 30 may be an emissive display device such as an organic light emitting diode (OLED) display, an inorganic emissive display device, a quantum dot emissive display device, and the like. The display device 30 may be disposed in a space defined by the cover window 10 and the housing 20.

The electronic device 1 may have various shapes. For example, the electronic device 1 may be a quadrangle with rounded corners when viewed from the front, as shown in FIG. 1. In addition, the electronic device 1 may have a rectangular shape, a square, other shapes such as a polygon, a circle, an oval, and the like (e.g., in a plan view).

The electronic device 1 and the display device 30 may include display panels DP. Each display panel DP may include a display area DA and a peripheral area NA. The display area DA and the peripheral area NA shown in FIG. 1A may correspond to a display area DA and a peripheral area NA of the display device 30 shown in FIG. 1B. The display area DA is a region where the image is displayed and may correspond to the display screen. The peripheral area NA is a region where the image is not displayed. In an embodiment, the display area DA may occupy most of the region centered on the front side of the electronic device 1, and the peripheral area NA may surround the display area DA (e.g., in a plan view).

In an embodiment, the display area DA may include a first display area DA1, a second display area DA2, and a third display area DA3. In an embodiment, the second display area DA2 and third display area DA3 may be regions where components such as sensors and cameras are placed on the back to add various functions to the electronic device 1. For example, the second display area DA2 and the third display area DA3 may correspond to a component region. In an embodiment, the second display area DA2 and the third display area DA3 may be surrounded by the first display area DA1 (e.g., in a plan view). The first display area DA1, the second display area DA2, and the third display area DA3 may all display images. The position and number of the second display area DA2 and the third display area DA3 may be changed in various ways.

The peripheral area NA is a region that does not provide an image and may entirely surround the display area DA (e.g., in a plan view). A driver or a main power line to provide electrical signals or power to subpixel circuits may be disposed in the peripheral area NA. In an embodiment, the peripheral area NA may include a pad, which is a region to which electronic components or a printed circuit board (PCB) may be electrically connected.

Referring to FIG. 1C, in an embodiment electronic modules EM1 and EM2 may include a first electronic module EM1 and a second electronic module EM2. The display device 30, the power supply module PM, the first electronic module EM1, and the second electronic module EM2 may be electrically connected to each other. FIG. 1C illustrates an example of a subpixel P and a touch sensor TS disposed in the display area DA among the configurations of the display device 30.

The power supply module PM may supply the power required for the overall operation of the electronic device 1. The power supply module PM may include a typical battery module.

The first electronic module EM1 and the second electronic module EM2 may include various functional modules for operation of the electronic device 1. In an embodiment, the first electronic module EM1 may be mounted directly on a motherboard and electrically connected to the display device 30, or it may be mounted on a separate substrate and electrically connected to the motherboard via a connector.

In an embodiment, the first electronic module EM1 may include a control module CM, a wireless communication module TM, an image input module IIM, an audio input module AIM, a memory MM, and an external interface IF. Some of the modules may not be mounted on the motherboard, but may be electrically connected to the motherboard via a flexible printed circuit substrate.

The control module CM may control overall operation of the electronic device 1. For example, in an embodiment the control module CM may be a microprocessor. For example, the control module CM may activate or deactivate the display device 30. The control module CM may control other modules such as an image input module IIM or an audio input module AIM based on a touch signal received from the display device 30.

In an embodiment, the wireless communication module TM may transmit/receive wireless signals with other terminals using a Bluetooth or WiFi line. The wireless communication module TM may transmit and receive voice signals using general communication lines. The wireless communication module TM includes a transmitting portion TM1 that modulates and transmits a signal to be transmitted, and a receiving portion TM2 that demodulates a signal to be received.

The image input module IIM may process an image signal and convert it into image data that can be displayed on the display device 30. In an embodiment, the audio input module AIM may receive external audio signals from a microphone in recording mode, voice recognition mode, and the like and convert them into electrical voice data.

The external interface IF may serve as an interface connected to an external charger, wired/wireless data port, card socket (e.g., memory card, SIM/UIM card), and the like.

In an embodiment, the second electronic module EM2 may include an audio output module AOM, a light emitting module LM, a light receiving module LRM, a camera module CMM, and the like, and at least some of them may be disposed on a rear surface of the display device 30 as an optical element ES. For example, the optical element ES may include the light emitting module LM, the light receiving module LRM, and the camera module CMM. In addition, the second electronic module EM2 may be mounted directly on the motherboard, or on a separate substrate and electrically connected to the display device 30 via a connector, or may be electrically connected to a first electronic module EM1.

The audio output module AOM may convert audio data received from the wireless communication module TM or audio data stored in the memory MM and output it to the outside.

The light emitting module LM may generate and output light. The light emitting module LM may output infrared light. For example, the light emitting module LM may include an LED element. For example, the light receiving module LRM may detect infrared light. The light receiving module LRM may be activated when infrared light above a certain level is detected. For example, in an embodiment the light receiving module LRM may include a CMOS sensor. After the infrared light generated from the light emitting module LM is output, it may be reflected by an external object (e.g., user's finger or face), and the reflected infrared light may be incident on the light receiving module LRM. The camera module CMM may capture images of the outside (e.g., the external environment).

In an embodiment, the optical element ES may additionally include a light detecting sensor or a heat detecting sensor. The optical element ES may detect an external subject received through the front or provide a sound signal such as voice to the outside through the front. In addition, the optical element ES may include a plurality of configurations and is not necessarily limited to any one embodiment.

Referring to FIG. 1D, various electronic devices to which the display device according to embodiments may include an image display electronic device such as a smart phone 1_1a, a tablet PC 1_1b, a laptop 1_1c, a TV 1_1d, a monitor 1_1e, and the like, a wearable electronic device including a display module such as a smart spectacles 1_2a, a head-mount display 1_2b, a smart watch 1_2c, and the like, and a vehicle electronic device 1_3 including a display module such as a vehicle instrument panel (e.g., substrate), a center fascia, a center information display (CID) placed on the dashboard, and a room mirror display.

Referring to FIG. 1E, in an embodiment the display device 30 may provide a display screen in the electronic device 1. The display device 30 may detect or capture the front of the electronic device 1. The display device 30 may have a similar flat shape to the electronic device 1.

Each subpixel P of the display area DA of the display device 30 may be defined as a region that can emit light of a predetermined color. In an embodiment, the display area DA includes subpixels P connected to a scan line SL extending in the first direction DR1 and a data line and a driving voltage line extending in the second direction DR2 intersecting the first direction. The display device 30 may provide an image using light emitted from subpixels P. For example, in an embodiment each subpixel P may emit red, green, and blue or white light. However, embodiments of the present disclosure are not necessarily limited thereto and the colors emitted by the subpixel P may vary.

Each of the subpixels P may emit light of a predetermined color using a light emitting diode, for example, an organic light emitting diode. In an embodiment, each organic light emitting diode may emit, for example, red, green, and blue or white light. Each organic light emitting diode may be connected to (e.g., electrically connected thereto) a subpixel circuit containing a thin film transistor and a capacitor.

The peripheral area NA may surround the display area DA (e.g., in a plan view). The peripheral area NA may be defined as an edge area of the main area MA of the display panel DP. Circuits and/or signal lines for generating and/or transmitting various signals applied to the display area DA may be arranged in the peripheral area NA. For example, in an embodiment a gate driver that supplies gate signals to gate lines, and fan-out lines FW that connect the signal lines of the display driver 50 and the display area DA may be disposed in the peripheral area NA,.

In an embodiment, a region extending from one side of the peripheral area NA may include a flexible region capable of bending, folding, rolling, and the like. For example, the peripheral area NA may include a bending area BA. The bending area BA is bendable and may overlap the display area DA in a thickness direction (e.g., the first direction DR3) when in the bent configuration, and accordingly a width of the peripheral area NA viewed by a user may be reduced.

In an embodiment, a display driver 50 may be disposed in the peripheral area NA, and a pad portion 40 may be disposed at an edge of the peripheral area NA.

In an embodiment, the pad portion 40 may include pads for connection with a controller. The pad portion 40 is exposed and not covered by the insulation layer and may be electrically connected to a controller, such as a flexible printed circuit board (FPCB) or an IC chip.

The display driver 50 may output signals and voltages to drive the display panel DP. The display driver 50 may supply data voltages to data lines. The display driver 50 may supply a power voltage to power lines, and may supply gate control signals to a gate driver. In an embodiment, the display driver 50 may be provided as an IC chip and mounted on the display panel DP. For example, the display driver 50 may be disposed in the peripheral area NA, and may overlap the display area DA in a thickness direction (e.g., the third direction DR3) due to the bending of the peripheral area NA.

In an embodiment, the touch driver may be provided as an IC chip and mounted on the controller 90. The touch driver may be electrically connected to a touch detector included in the electronic device 1. The touch detector may be provided in the display area DA of the display panel DP. In an embodiment, the touch driver may supply an input signal (e.g., a touch driving signal) to sensing electrodes of the touch detector, and detect a change in capacitance between the sensing electrodes based on an output signal (e.g., touch detection signal) from the sensing electrodes. For example, the touch driving signal may be a pulse signal having a predetermined frequency. The touch driver may calculate whether a touch has occurred and touch coordinates based on the change in capacitance between the sensing electrodes.

The controller changes a plurality of video signals transmitted from the outside into a plurality of image data signals and transmits the changed signals to the display driver 50 through the pad. In addition, the display driver 50 may generate a data signal, and the generated data signal may be transmitted to the display area DA through fan-out lines FW. In addition, the controller 90 may receive a vertical synchronization signal, a horizontal synchronizing signal, and a clock signal, generate a control signal for driving and transmits to a scan driver through a pad. In an embodiment, the controller may transmit a driving voltage ELVDD and a common voltage ELVSS to a driving voltage supply line and a common voltage supply line respectively through the pad.

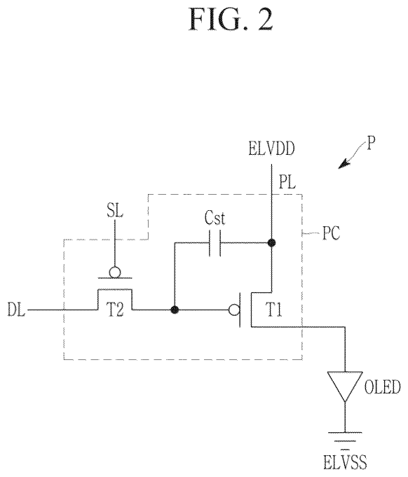

FIG. 2 shows a light emitting diode of the display device and a subpixel circuit PC connected to the light emitting diode according to an embodiment.

Referring to FIG. 2, as a light emitting diode, an organic light emitting diode OLED is connected to the subpixel circuit PC. In an embodiment, the subpixel circuit PC may include a first thin film transistor T1, a second thin film transistor T2, and a storage capacitor Cst.

In an embodiment, the second thin film transistor T2 is a switching thin film transistor, and is connected to a scan line SL and a data line DL and may transmit a data voltage input from the data line DL according to a switching voltage input from the scan line SL to the first thin film transistor T1. The storage capacitor Cst is connected with the second thin film transistor T2 and a driving voltage line PL, and may store a voltage corresponding to a difference between a voltage transmitted from the second thin film transistor T2 and the driving voltage ELVDD supplied to the driving voltage line PL.

In an embodiment, the first thin film transistor T1 is a driving thin film transistor, and is connected with the driving voltage line PL and the storage capacitor Cst and control a driving current flowing through the organic light emitting diode OLED from the driving voltage line PL corresponding to the voltage stored in the storage capacitor Cst. The organic light emitting diode OLED may emit light with a predetermined luminance depending on the driving current. A subpixel electrode (e.g., anode) of the organic light emitting diode OLED may be connected to the subpixel circuit PC, and an opposed electrode (e.g., cathode) of the organic light emitting diode OLED may be supplied with the common voltage ELVSS.

FIG. 2 illustrates that the subpixel circuit PC includes two thin film transistors and one storage capacitor. However, embodiments of the present disclosure are not necessarily limited thereto and the number of the thin film transistors and storage capacitors may vary.

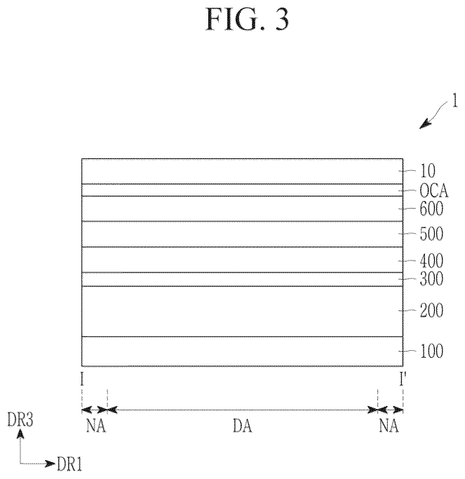

FIG. 3 is a cross-sectional view that schematically illustrates a display device according to an embodiment, and is a cross-sectional view of the display device of FIG. 1E, taken along the line I-I′.

Referring to FIG. 3, in an embodiment an electronic device 1 may include a substrate 100, a display layer 200, a low reflective layer 300, an encapsulation layer 400, a touch sensor layer 500, anti-reflection layer 600, an adhesive layer OCA, and a cover window 10.

The substrate 100 may include glass or polymer resin. For example, in an embodiment the polymer resin may include polyethersulfone, polyacrylate, polyether imide, polyethylene naphthalate, polyethylene terephthalate, polyphenylene sulfide, polyarylate, polyimide, polycarbonate, or cellulose acetatepropionate. The substrate 100 may include a flexible material such as a plastic that can be bent, folded, or rolled, or may include a rigid substrate. In an embodiment, the substrate 100 may form a multi-layer structure including a layer containing polymer resin and an inorganic layer.

The display layer 200 may include a light emitting diode, a thin film transistor electrically connected to, for example, the organic light emitting diode, for example, organic light emitting diode, and insulation layers disposed between the light emitting diode and the thin film transistor.

In an embodiment, a low reflective layer may be disposed on the display layer 200, and the encapsulation layer 400 may be disposed on the low reflective layer. For example, the display layer 200 and/or the low reflective layer may be encapsulated by the encapsulation layer 400. However, embodiments of the present disclosure are not necessarily limited thereto. For example, in an embodiment the low reflective layer may be omitted. In this embodiment, the encapsulation layer 400 may be directly disposed on the display layer 200. The encapsulation layer 400 may include at least one inorganic encapsulation layer and at least one organic encapsulation layer.

In some embodiments, instead of the encapsulation layer 400, an encapsulation substrate formed of a glass material may be provided. The encapsulation substrate may be disposed on the display layer 200, and the display layer 200 may be disposed between the substrate 100 and the encapsulation substrate. A gap may exist between the encapsulation substrate and the display layer 200, which may be filled with a filler material.

The touch sensor layer 500 may be disposed on the encapsulation layer 400 (e.g., disposed directly thereon in a third direction DR3). In an embodiment, the touch sensor layer 500 may detect an external input, for example, a touch of an object such as a finger or a stylus pen, such that the display device 30 can obtain coordinate information corresponding to the touch position. The touch sensor layer 500 may include a touch electrode and trace lines connected to the touch electrode. The touch sensor layer 500 may detect an external input using a mutual capacitance or self-capacitancemethod.

In an embodiment, the encapsulation layer 400 may be directly formed on the touch sensor layer 500. Alternatively, after being separately formed, the touch sensor layer 500 may be adhered onto the encapsulation layer 400 through an adhesive layer OCA such as an optically clear adhesive.

The anti-reflection layer 600 may be disposed on the touch sensor layer 500 (e.g., disposed directly thereon in a third direction DR3). The anti-reflection layer 600 may reduce the reflectivity of external light incident on the display device 30 from the outside (e.g., the external environment) through the cover window 10.

The anti-reflection layer 600 may not include a polarizer. A polarizer not only reduces the reflection of external light, but also reduces the light emitted from the display layer 200, which has the drawback of consuming more electric power to display a certain luminance. Therefore, to reduce power consumption, the display device 30 according to an embodiment may not include a polarizer.

In an embodiment, the anti-reflection layer 600 may include a light blocking layer and color filters. The color filters may be arranged based on a color of light emitted from each of the light emitting diodes of the display layer 200.

The cover window 10 may be disposed on the anti-reflection layer 600. The cover window 10 may protect a display panel. In an embodiment, after being separately formed, the cover window 10 may be adhered to the anti-reflection layer 600 by an adhesive layer OCA interposed between the cover window 10 and the anti-reflection layer 600 (e.g., in the third direction DR3). The adhesive layer OCA may be, for example, an optically clear adhesive. Alternatively, in an embodiment the cover window 10 may be directly formed on the anti-reflection layer 600 (e.g., in the third direction DR3) and the adhesive layer OCA may not be included.

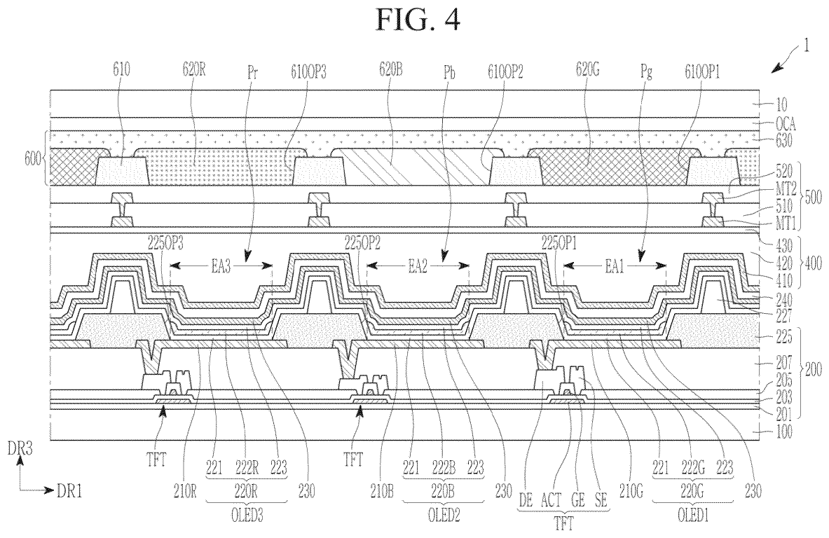

FIG. 4 is a schematic cross-sectional view of a display device according to an embodiment. Hereinafter, referring to FIG. 4, a stacking structure of the display device 30 will be described in more detail.

The display device 30 may include a plurality of subpixels disposed in the display area DA (refer to FIG. 3). In an embodiment, a plurality of subpixels each may emit red, green, or blue light. A plurality of subpixels may include subpixels that emit different colors from each other, for example, a first subpixel, a second subpixel, and a third subpixel. The first subpixel, the second subpixel, and the third subpixel may each be provided in plurality. In an embodiment, a first subpixel may be a green subpixel Pg that emits light of green, the second subpixel may be a blue subpixel Pb that emits light of blue, and the third subpixel may be a red subpixel Pr that emits light of red.

The display layer 200 may be disposed on the substrate 100 (e.g., disposed directly thereon in a third direction DR3). The display layer 200 may include a subpixel circuit layer and a light emitting diode layer. In an embodiment, the subpixel circuit layer includes a thin film transistor TFT, and may include a buffer layer 201, a gate insulation layer 203, an interlayer insulating layer 205, a planarization layer 207, which are insulation layers.

The buffer layer 201 may be disposed on the substrate 100 (e.g., disposed directly thereon in a third direction DR3). However, embodiments of the present disclosure are not necessarily limited thereto and the buffer layer 201 may be omitted in some embodiments. In an embodiment, the buffer layer 201 may include silicon nitride (SiNₓ), silicon oxide (SiOₓ), silicon oxynitride, and the like. The buffer layer 201 is disposed between the substrate 100 and a semiconductor layer ACT (e.g., in the third direction DR3), and blocks impurity from the substrate 100 during a crystallization process to form polycrystalline silicon, thereby increasing the characteristics of the polycrystalline silicon, and planarizing the substrate 100 may relieve the stress of the semiconductor layer ACT formed on the buffer layer BF.

The thin film transistor TFT may be disposed on the buffer layer 201 (e.g., disposed directly thereon in the third direction DR3). The thin film transistor TFT may include a semiconductor layer ACT, a gate electrode GE, a source electrode SE, and a drain electrode DE. The thin film transistor TFT may be connected to (e.g., electrically connected thereto) an organic light emitting diode to drive the same.

The semiconductor layer ACT may be disposed on the buffer layer 201 (e.g., disposed directly thereon in the third direction DR3). In an embodiment, the semiconductor layer ACT may include polysilicon or amorphous silicon. Alternatively, the semiconductor layer ACT may include an oxide of at least one or more materials selected from a group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region which are doped with an impurity.

The gate electrode GE, the source electrode SE, and the drain electrode DE may be formed of various conductive materials. In an embodiment, the gate electrode GE may include at least one of molybdenum (Mo), aluminum (Al), copper (Cu), and titanium (Ti). For example, the gate electrode GE may be a single layer of molybdenum (Mo) or a triple-layered structure including a molybdenum (Mo) layer, an aluminum (Al) layer, and a molybdenum (Mo) layer. In an embodiment, the source electrode SE and the drain electrode DE may include at least one material selected from a group consisting of copper (Cu), titanium (Ti), and aluminum (Al). For example, the source electrode SE and the drain electrode DE may form a triple-layered structure including a titanium (Ti) layer, an aluminum (Al) layer, and a titanium (Ti) layer.

In an embodiment, the gate insulation layer 203 may be disposed between the semiconductor layer ACT and the gate electrode GE (e.g., in the third direction DR3) to ensure insulation between the semiconductor layer ACT and the gate electrode GE. An interlayer insulating layer 205 may be disposed on (e.g., disposed directly thereon) the gate electrode GE, and the source electrode SE and the drain electrode DE may be disposed on the interlayer insulating layer 205.

In an embodiment, the gate insulation layer 203 and the interlayer insulating layer 205 each may include an inorganic material such as silicon oxide, silicon nitride, and/or silicon oxynitride. In an embodiment, the gate insulation layer 203 and the interlayer insulating layer 205 may be formed through, for example, a chemical vapor deposition (CVD) method or an atomic layer deposition (ALD) method.

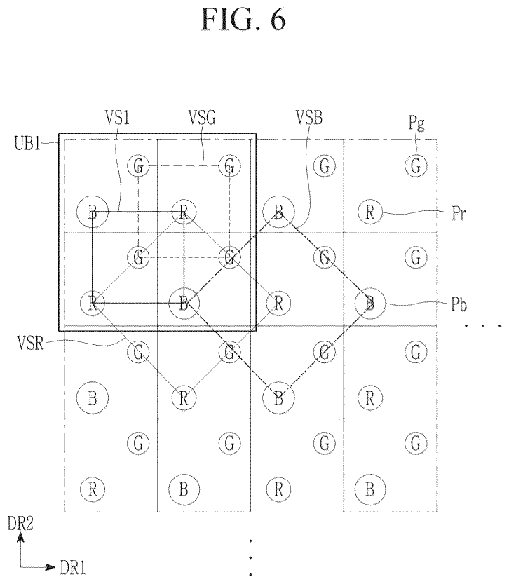

The planarization layer 207 may be disposed on (e.g., disposed directly thereon) the thin film transistor TFT. In an embodiment, to provide a flat upper surface, chemical and mechanical polishing may be performed on an upper surface of the planarization layer 207 after forming the planarization layer 207. In an embodiment, the planarization layer 207 may include a general polymer such as photosensitivity polyimide, polyimide, polystyrene (PS), polycarbonate, benzocyclobutene (BCB), hexamethyldisiloxane (HMDSO), polymethylmethacrylate (PMMA), or polystyrene (PS), a polymer derivative having a phenol group, an acryl-based polymer, an imide polymer, an arylther polymer, an amide polymer, a fluorine polymer, a p-xylene polymer, or a vinylalcohol polymer. In FIG. 4, the planarization layer 207 is illustrated as a single layer. However, embodiments of the present disclosure are not necessarily limited thereto and the planarization layer 207 may be multi-layered in some embodiments. The planarization layer 207 may include a first insulation layer, a second insulation layer, and a third insulation layer (VIA1, VIA2, and VIA3 of FIG. 6). In an embodiment, subpixel electrodes 210G, 210B, and 210R of first to third organic light emitting diodes OLED1, OLED2, and OLED3 may be electrically connected to the thin film transistor TFT through a contact hole of the planarization layer 207.

The light emitting diode layer may be disposed on the subpixel circuit layer. In an embodiment, the light emitting diode layer may include the first to third organic light emitting diodes OLED1, OLED2, and OLED3, a partition wall 225, and a spacer 227.

The first to third organic light emitting diodes OLED1, OLED2, and OLED3 may be disposed on the subpixel circuit layer. In an embodiment, the first organic light emitting diode OLED1 may include a stacking structure of the subpixel electrode 210G, an intermediate layer 220G including a first common layer 221, a light emitting layer 222G, and a second common layer 223, and an opposed electrode 230 (e.g., an opposite electrode), the second organic light emitting diode OLED2 may include a stacking structure of the subpixel electrode 210B, an intermediate layer 220 including a first common layer 221, a light emitting layer 222B, and a second common layer 223, and an opposed electrode 230 (e.g., an opposite electrode), and the third organic light emitting diode OLED3 may include a stacking structure of the subpixel electrode 210R, a first common layer 221, a light emitting layer 222R, and a second common layer 223, and an opposed electrode 230 (e.g., an opposite electrode).

The subpixel electrodes 210G, 210B, and 210R may be disposed on the planarization layer 207 (e.g., disposed directly thereon in the third direction DR3). The subpixel electrodes 210G, 210B, and 210R may be disposed spaced apart from each other (e.g., in a first direction DR1).

The subpixel electrodes 210G, 210B, and 210R may be reflecting electrodes. In an embodiment, the subpixel electrodes 210G, 210B, and 210R may be provided with a reflective film including silver (Ag), magnesium (Mg), aluminum (Al), platinum (Pt), palladium (Pd), gold (Au), nickel (Ni), neodymium (Nd), iridium (Ir), chromium (Cr) and a compound thereof, and a transparent or semi-transparent conductive layer formed on the reflective layer. The transparent or semi-transparent conductive layer may include at least one or materials selected from a group consisting of indium tin oxide (ITO), indium zinc oxide (IZO), zinc oxide (ZnO), indium oxide (In₂O₃), indium gallium oxide (IGO), and aluminum zinc oxide (AZO).

The partition wall 225 may be disposed on (e.g., disposed directly thereon) the subpixel electrodes 210G, 210B, and 210R and the planarization layer 207. In an embodiment, the partition wall 225 may cover edges of the subpixel electrodes 210G, 210B, and 210R.

The partition wall 225 may include a plurality of lower openings that define a light emitting area of each subpixel while overlapping the subpixel electrodes 210G, 210B, and 210R. For example, the lower openings of the partition wall 225 may expose a central portion of the subpixel electrodes 210G, 210B, and 210R. The first to third lower openings 225OP1, 225OP2, and 225OP3 of the partition wall 225 may define first to third light emitting areas EA1, EA2, and EA3 of the first to third organic light emitting diodes OLED1, OLED2, and OLED3 included in each subpixel. As shown in FIG. 4, the partition wall 225 may include a first lower opening 225OP1 that defines the first light emitting area EA1 of the first organic light emitting diode OLED1 of the first subpixel. In addition, the partition wall 225 may include a second lower opening 225OP2 that defines the second light emitting area EA2 of the second organic light emitting diode OLED2 of the second subpixel, and a third lower opening 225OP3 that defines the third light emitting area EA3 of the third organic light emitting diode OLED3 of the third subpixel.

In an embodiment, the partition wall 225 may include an organic insulator. Alternatively, the partition wall 225 may include an inorganic insulator such as silicon nitride or silicon oxide. In some embodiments, the partition wall 225 may include an organic insulator and an inorganic insulator.

In an embodiment, the partition wall 225 may include a light blocking material. For example, the light blocking material of the partition wall 225 may be black. In an embodiment, the light blocking material may include a resin or paste containing carbon black, carbon nanotube, black dye, a metal particle such as nickel, aluminum, molybdenum, and an alloy thereof, a metal oxide particle, a metal nitride particle, and the like. In an embodiment in which the partition wall 225 includes a light blocking material, the external light reflection caused due to the metal structures disposed below the partition wall 225 may be reduced.

The spacer 227 may be disposed on the partition wall 225 (e.g., disposed directly thereon in the third direction DR3). in an embodiment, the spacer 227 may include an organic insulator such as polyimide. Alternatively, the spacer 227 may include an inorganic insulator such as silicon nitride or silicon oxide, or may include an organic insulator and an inorganic insulator. In an embodiment, the spacer 227 may include a material different from the partition wall 225 including the light blocking material described above, and may be formed in separate processes.

In an embodiment, the spacer 227 may include the same material as that of the partition wall 225. In this embodiment, the partition wall 225 and the spacer 227 may be formed together in a mask process using a half-tone mask and the like.

An intermediate layer may be disposed on the subpixel electrodes 210G, 210B, and 210R and the partition wall 225 (e.g., in the third direction DR3). As described above, the intermediate layer may include a first common layer 221, a light emitting layer, and a second common layer 223.

The light emitting layers 222G, 222B, and 222R may be disposed inside the first to third lower openings 225OP1, 225OP2, and 225OP3 of the partition wall 225. In an embodiment, the light emitting layers 222G, 222B, and 222R may be organic materials including fluorescent or phosphorescence materials that can emit green, blue, or red light. The above-stated organic material may be a low molecular organic material or a polymer organic material.

The first common layer 221 and the second common layer 223 may be disposed above and below the light emitting layer, respectively (e.g., in the third direction DR3). In an embodiment, the first common layer 221 may include, for example, a hole transport layer (HTL), or a hole transport layer and a hole injection layer (HIL). The second common layer 223 may include, for example, an electron transport layer (ETL), or an electron transport layer (ETL) and an electron injection layer (EIL). However, embodiments of the present disclosure are not necessarily limited thereto. For example, in an embodiment, the second common layer 223 may not be provided.

In an embodiment, while the light emitting layer is disposed for each subpixel to correspond to the first to third lower openings 225OP1, 225OP2, and 225OP3 of the partition wall 225, the first common layer 221 and the second common layer 223 may be integrally formed to entirely cover the substrate 100, respectively. For example, the first common layer 221 and the second common layer 223 may be integrally formed to entirely cover the display area DA of the substrate 100, respectively.

The opposed electrode 230 (e.g., opposite electrode) may be a cathode, which is an electron injection electrode. Such an opposed electrode 230 may include a conductive material having a low work function. For example, in an embodiment the opposed electrode 230 may include a (semi)transparent layer containing silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposed electrode 230 may further include a layer such as ITO, IZO, ZnO or In₂O₃ on the (semi)transparent layer containing the aforementioned material.

According to an embodiment, a capping layer 240 may be disposed on the display layer 200. The capping layer 240 may be disposed on the first to third organic light emitting diodes OLED1, OLED2, and OLED3. In an embodiment, the capping layer 240 may serve to increase the luminous efficiency of the first to third organic light emitting diodes OLED1, OLED2, and OLED3 by the principle of constructive interference.

The capping layer 240 may be an organic capping layer including an organic material, an inorganic capping layer including an inorganic material, or a composite capping layer including an organic material and an inorganic material. For example, in an embodiment the capping layer 240 may include a carbocyclic compound, a heterocyclic compound, an amine group-containing compound, a porphine derivative, a phthalocyanine derivative, a naphthalocyanine derivative, an alkali metal a complex, an alkaline-earth metal a complex, or any combination thereof. The carbocyclic compound, the heterocyclic compound, and the amine group-containing compound may be selectively substituted with substituents including O, N, S, Se, Si, F, CI, Br, I, or any combination thereof.

The encapsulation layer 400 may be disposed on (e.g., disposed directly thereon) the capping layer 240. The encapsulation layer 400 may seal the display layer 200 and block the inflow of external moisture and oxygen. The encapsulation layer 400 may include at least one inorganic encapsulation layer and at least one organic encapsulation layer. For example, as shown in FIG. 4, in an embodiment the encapsulation layer 400 may include a first inorganic encapsulation layer 410, an organic encapsulation layer 420, and a second inorganic encapsulation layer 430, which are sequentially stacked (e.g., in the third direction DR3).

In an embodiment, the first inorganic encapsulation layer 410 and the second inorganic encapsulation layer 430 may include an inorganic insulator such as silicon oxide, silicon nitride, silicon oxynitride, aluminum oxide, titanium oxide, tantalum oxide, hafnium oxide, zinc oxide, and the like. The first inorganic encapsulation layer 410 and the second inorganic encapsulation layer 430 may be a single-layer or multi-layer structure including the above-described inorganic insulator.

The organic encapsulation layer 420 may relieve the internal stress of the first inorganic encapsulation layer 410 and/or the second inorganic encapsulation layer 430. The organic encapsulation layer 420 may include a polymer-based material. For example, in an embodiment the organic encapsulation layer 420 may include polyethylene terephthalate, polyethylene naphthalate, polycarbonate, polyimide, polyethylene sulfonate, polyoxymethylene, polyacrylate, hexamethyldisiloxane, acryl-based resin (e.g., polymethylmethacrylate, polyacrylate, and the like), or a combination thereof.

In an embodiment, the encapsulation layer 400 may have a multi-layer structure of a first inorganic encapsulation layer 410, an organic encapsulation layer 420, and a second inorganic encapsulation layer 430. In this embodiment, although a crack occurs in the encapsulation layer 400, the crack may not propagate between the first inorganic encapsulation layer 410 and the organic encapsulation layer 420 or between the organic encapsulation layer 420 and the second inorganic encapsulation layer 430.

The touch sensor layer 500 may be disposed on the encapsulation layer 400 (e.g., in the third direction DR3). In an embodiment, the touch sensor layer 500 may include a first touch electrode MT1, a first touch insulation layer 510, a second touch electrode MT2, and a second touch insulation layer 520. In an embodiment, the first touch electrode MT1 may be directly disposed on the encapsulation layer 400. For example, the first touch electrode MT1 may be directly disposed on the second inorganic encapsulation layer 430 of the encapsulation layer 400. However, embodiments of the present disclosure are not necessarily limited thereto.

In an embodiment, the touch sensor layer 500 may include an insulation layer disposed between the first touch electrode MT1 and the encapsulation layer 400. In this embodiment, the insulation layer is disposed on the second inorganic encapsulation layer 430 of the encapsulation layer 400, and thus a surface on which the first touch electrode MT1 and the like are formed may be planarized. In an embodiment, the insulation layer may include an inorganic insulator such as silicon oxide, silicon nitride, silicon oxynitride, and the like. In some embodiments, the insulation layer may include an organic insulator.

The first touch insulation layer 510 may be disposed on (e.g., disposed directly thereon) the first touch electrode MT1. The first touch insulation layer 510 may be formed of an inorganic material or an organic material. In an embodiment in which the first touch insulation layer 510 is formed of an inorganic material, the first touch insulation layer 510 may include at least one or more materials selected from a group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In an embodiment in which the first touch insulation layer 510 is formed of an organic material, the first touch insulation layer 510 may include at least one or more materials selected from a group including acryl-based resin, methacryl-based resin, polyisoprene, vinyl-based resin, epoxy-based resin, urethane-based resin, cellulose-based resin, and perylene-based resin.

The second touch electrode MT2 may be disposed on the first touch insulation layer 510 (e.g., disposed directly thereon in the third direction DR3). In an embodiment, the second touch electrode MT2 may serve as a sensor that detects the user's touch input. The first touch electrode MT1 may serve as a connection portion that connects the patterned second touch electrode MT2 in one direction. In an embodiment, both the first touch electrode MT1 and the second touch electrode MT2 may serve as sensors. In this embodiment, the first touch electrode MT1 and the second touch electrode MT2 may be electrically connected through the contact hole. In an embodiment in which both the first touch electrode MT1 and the second touch electrode MT2 serve as sensors, the resistance of the touch electrodes is reduced, allowing the user's touch input to be detected relatively quickly.

In an embodiment, the first touch electrode MT1 and the second touch electrode MT2 may have a structure, for example, a mesh structure, through which light emitted from an organic light emitting diode may pass. In this embodiment, the first touch electrode MT1 and the second touch electrode MT2 may not overlap with a light emitting area EA of the organic light emitting diode.

The first touch electrode MT1 and the second touch electrode MT2 may include a metal layer or a transparent conductive layer. In an embodiment, the metal layer may include molybdenum (Mo), silver (Ag), titanium (Ti), copper (Cu), aluminum (Al), and an alloy thereof. The transparent conductive layer may include a transparent conductive oxide such as indium tin oxide (ITO), indium zinc oxide (IZO), zinc oxide (ZnO), or indium tin zinc oxide (ITZO), a conductive polymer such as PEDOT, a metal nano wire, carbon nanotube, or graphene.

The second touch insulation layer 520 may be disposed on (e.g., disposed directly thereon)I the second touch electrode MT2. The second touch insulation layer 520 may be formed of an inorganic material or an organic material. In an embodiment in which the second touch insulation layer 520 is formed of an inorganic material, the second touch insulation layer 520 may include at least one or more materials selected from a group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In an embodiment in which the second touch insulation layer 520 is formed of an organic material, the second touch insulation layer 520 may include at least one or more materials selected from a group consisting of acryl-based resin, methacryl-based resin, polyisoprene, vinyl-based resin, epoxy-based resin, urethane-based resin, cellulose-based resin, and perylene-based resin.

In some embodiments, the touch sensor layer 500 may include the first touch electrode MT1, the first touch insulation layer 510, and the second touch electrode MT2, and may not include the second touch insulation layer 520. In this embodiment, the anti-reflection layer 600 may be provided as a structure covering the second touch electrode MT2.

The anti-reflection layer 600 may be disposed on the touch sensor layer 500 (e.g., in the third direction DR3). In an embodiment, the anti-reflection layer 600 is provided such that a polarizer may not be included on the touch sensor layer 500 or the second touch insulation layer 520. The polarizer may prevent the display device from being deteriorated due to external light that is reflected from the subpixel electrodes 210G, 210B, and 210R or sidewalls of the first to third lower openings 225OP1, 225OP2, and 225OP3 of the partition wall 225 and is visible to the user. However, the polarizer not only reduces the reflection of external light, but also reduces the light emitted from the display layer 200, and thus more electric power may be consumed to display a certain luminance. Therefore, in an embodiment a polarizer may not be included for reduction of power consumption.

A cover window 10 may be disposed on the anti-reflection layer 600 with an adhesive layer OCA in between (e.g., in the third direction DR3).

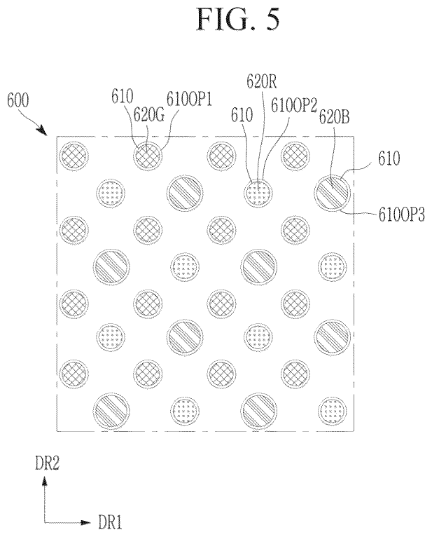

Hereinafter, referring to FIG. 4 and FIG. 5, the anti-reflection layer 600 will be described. FIG. 5 is a schematic top plan view of the anti-reflection layer of the display device according to an embodiment.

The anti-reflection layer 600 may include a light blocking layer 610 and a plurality of color filters. In an embodiment, the anti-reflection layer 600 may include first to third color filters 620G, 620B, and 620R of different colors corresponding to first to third organic light emitting diodes OLED1, OLED2, and OLED3, respectively. The first to third color filters 620G, 620B, and 620R each may be provided in plurality.

The light blocking layer 610 is disposed above the partition wall 225 (e.g., in the third direction DR3) and may have a plurality of upper openings that overlap with a plurality of lower openings. In an embodiment, the light blocking layer 610 may have first to third upper openings 610OP1, 610OP2, and 610OP3 corresponding to first to third color subpixels, respectively. The light blocking layer 610 may include a first upper opening 610OP1 corresponding to the first light emitting area EA1, a second upper opening 610OP2 corresponding to the second light emitting area EA2, and a third upper opening 6100P3 corresponding to the third light emitting area EA3. Light emitting from the first to third organic light emitting diodes OLED1, OLED2, and OLED3 may be emitted to the outside (e.g., the external environment) through the first to third upper openings 610OP1, 610OP2, and 610OP3 of the light blocking layer 610.

The first upper opening 610OP1 of the light blocking layer 610 may overlap the first lower opening 225OP1 of the partition wall 225 (e.g., in the third direction DR3), the second upper opening 610OP2 may overlap the second lower opening 225OP2 (e.g., in the third direction DR3), and the third upper opening 610OP3 may overlap the third lower opening 225OP3 (e.g., in the third direction DR3). In FIG. 5, the first to third upper openings 610OP1, 610OP2, and 610OP3 are illustrated as circular (e.g., in a plan view), but are not necessarily limited thereto and may have various shapes such as an oval (e.g., in a plan view).

In this specification, a width (or size) of each subpixel refers to a width (or size) of the light emitting area of the organic light emitting diode that implements each subpixel, and a width (or size) of the light emitting area may be defined by a width (or size) of the lower opening provided in the partition wall 225.

In an embodiment, a width (or size) of each of the first to third upper openings 610OP1, 610OP2, and 610OP3 of the light blocking layer 610 may be provided to be larger than a width (or size) of the corresponding subpixel among the first to third subpixels. For example widths (or sizes) of the first to third upper openings (610OP1, 610OP2, 610OP3) of the light blocking layer 610 may be larger than sizes (or widths) of the corresponding first to third lower openings 225OP1, 225OP2, and 225OP3 of the partition wall 225.

However, embodiments of the present disclosure are not necessarily limited thereto. For example, in an embodiment, a width (or size) of each of the first to third upper openings 610OP1, 610OP2, and 610OP3 of the light blocking layer 610 may be provided to be substantially the same as a width (or size) of the corresponding subpixel among the first to third subpixels. For example, the width (or size) of each of the first to third upper openings 610OP1, 610OP2, and 610OP3 of the light blocking layer 610 may be substantially the same as the width (or size) of each of the first to third lower openings 225OP1, 225OP2, and 225OP3 of the corresponding partition wall 225.

In an embodiment, the light blocking layer 610 may include an organic insulator. Alternatively, the light blocking layer 610 may include an inorganic insulator such as silicon nitride or silicon oxide. In some embodiments, the light blocking layer 610 may include an organic insulator and an inorganic insulator.

In an embodiment, the light blocking layer 610 may include a light blocking material. For example, the light blocking material of the light blocking layer 610 may be black. In an embodiment, the light blocking material may include a resin or paste containing carbon black, carbon nanotubes, black dye, metal particles such as nickel, aluminum, molybdenum, and an alloy thereof, metal oxide particles, or metal nitride particles. The light blocking layer 610 includes a light blocking material, thereby reducing external light reflection from metal structures disposed therebelow.

In an embodiment, first to third color filters 620G, 620B, and 620R may be disposed on the first to third upper openings 610OP1, 610OP2, and 610OP3 of the light blocking layer 610, respectively. The first to third color filters 620G, 620B, and 620R may have colors corresponding to the light emitted from the first to third light emitting areas EA1, EA2, and EA3. In an embodiment in which green light is emitted from the first light emitting area EA1, the first color filter 620G may be a green color filter. In an embodiment in which blue light is emitted from the second light emitting area EA2, the second color filter 620B may be a blue color filter. In an embodiment in which red light is emitted from the third light emitting area EA3, the third color filter 620R may be a red color filter.

The anti-reflection layer 600 may further include an overcoat layer 630. The overcoat layer 630 may be disposed on (e.g., disposed directly thereon) the light blocking layer 610 and the first to third color filters 620G, 620B, and 620R.

The overcoat layer 630 may planarize upper surfaces of the light blocking layer 610 and the first to third color filters 620G, 620B, and 620R.

The overcoat layer 630 is a colorless, translucent layer that has no color in the visible spectrum. In an embodiment, the overcoat layer 630 may include a colorless, light-transmitting organic material, such as an acrylic resin.

The display device and electronic device according to an embodiment may not include a polarizer on the overcoat layer 630. The polarizer may prevent the display device from being deteriorated due to external light that is reflected from the subpixel electrodes 210G, 210B, and 210R or sidewalls of the first to third lower openings 225OP1, 225OP2, and 225OP3 of the partition wall 225 and is visible to the user. However, the polarizer not only reduces the reflection of external light, but also reduces the light emitted from the display layer 200, and thus more electric power may be consumed to display a certain luminance. Therefore, in an embodiment a polarizer may not be included for reduction of power consumption.

FIG. 6 is a top plan view of the pixel arrangement of a portion of the display device according to an embodiment.

Referring to FIG. 6, a plurality of subpixels of the display device may include a first subpixel, a second subpixel, and a third subpixel. In an embodiment, the first subpixel may be a green subpixel Pg that can display green light G, the second subpixel may be a blue subpixel Pb that can display blue light B, and the third subpixel may be a red subpixel Pr that can display red light R. Hereinafter, it is assumed that the first subpixel is a green subpixel Pg, the second subpixel is a blue subpixel Pb, and the third subpixel is a red subpixel Pr for convenience of explanation.

In an embodiment, the red subpixel Pr, the blue subpixel Pb, and the green subpixel Pg may have an iterative array structure. The red subpixel Pr and the blue subpixel Pb may be disposed at corners of a virtual quadrangle VS1 centered at any one green subpixel Pg. The red subpixel Pr may be positioned at each vertex opposite to the green subpixel Pg along the diagonal direction of the virtual quadrangle VS1, and the blue subpixel Pb may be positioned at each vertex opposite to the green subpixel Pg along the diagonal direction of the virtual quadrangle VS1. In addition, the green subpixels Pg may be respectively positioned at the vertices of a virtual quadrangle VS2 centered on a subpixel (blue subpixel Pb or red subpixel Pr) disposed at any vertex of the virtual quadrangle VS1. In this embodiment, the virtual quadrangles VS1 and VS2 may be transformed into various shapes such as rectangular shape, rhombus, square, and the like.

In another way of expressing the arrangement of the subpixels in FIG. 6, the red subpixel Pr, the blue subpixel Pb, and the green subpixel Pg may be arranged in a penta-line (PENTILE™) structure, for example, a diamond penta-line structure. However, embodiments of the present disclosure are not necessarily limited thereto. For example, in some embodiments the red subpixel Pr, the blue subpixel Pb, and the green subpixel Pg may be arranged in a stripe structure. In addition, in some embodiments, the red subpixel Pr, the blue subpixel Pb, and the green subpixel Pg may be arranged in various subpixel arrangement structures, such as a mosaic structure, a delta structure, and the like.

The red subpixel Pr, the blue subpixel Pb, and the green subpixel Pg may have a circular shape (e.g., in a plan view). However, embodiments of the present disclosure are not necessarily limited thereto. In some embodiments, the red subpixel Pr, the blue subpixel Pb, and the green subpixel Pg may have the shape of an ellipse or a polygon (e.g., in a plan view). The shape of the polygon may include shapes with rounded vertices.

The red subpixel Pr, blue subpixel Pb, and green subpixel Pg may be different from each other in size (width). For example, in an embodiment the green subpixel Pg may be smaller than the red subpixel Pr and the blue subpixel Pb in size (width). The size (or width) of the blue subpixel Pb may be larger than the size (or width) of the red subpixel Pr. However, embodiments of the present disclosure are not necessarily limited thereto and numerous variations are possible, such as the sizes of the red subpixel Pr, the blue subpixel Pb, and the green subpixel Pg being substantially the same.

The subpixels of the display device may contain an iterative array structure of predetermined subpixel pattern unit blocks UB1. For example, the arrangement of the red subpixels Pr, the blue subpixels Pb, and the green subpixels Pg may correspond to an iterative arrangement of the predetermined subpixel pattern unit blocks UB1. The subpixel pattern unit blocks UB1 are virtual unit blocks having a predetermined area including the red subpixel Pr, the blue subpixel Pb, and the green subpixel Pg, and may be understood as corresponding to the minimum repeating unit of the arrangement pattern of subpixels provided in the display device. In an embodiment, the subpixel pattern unit blocks UB1 may have a rectangular shape. For example, the subpixel pattern unit block UB1 may be a square.

In an embodiment, the subpixel pattern unit blocks UB1 include red subpixels Pr, blue subpixels Pb, and green subpixels Pg, but the sum of the numbers of red subpixels Pr and blue subpixels Pb included in the subpixel pattern unit blocks UB1 may be equal to the number of green subpixels Pg. The subpixel pattern unit blocks UB1 illustrated in FIG. 5 include two red subpixels Pr, two blue subpixels Pb, and four green subpixels Pg.

Referring to FIG. 4 and FIG. 5, the display device 30 according to an embodiment includes the light blocking layer 610 and the anti-reflection layer 600 including the first to third color filters 620G, 620B, and 620R. In this embodiment, the light efficiency is excellent compared to a comparative embodiment in which the anti-reflection layer 600 includes a polarization film positioned on the front surface of the substrate 100, while the light reflected by each subpixel (e.g., the subpixel electrode or opposed electrode of each subpixel) may be relatively increased. Therefore, interference patterns due to diffraction of the reflected light from each subpixel of the display device 30 may increase. These interference patterns may be seen in an off-state of the display device 30, and as the interference patterns increase, they can become deteriorated in the off-state of the display device 30, such as by a double image. In addition, interference patterns may vary depending on the shape of the subpixels and a spacing between the subpixels. For example, a high-resolution display device 30 has a small gap between the subpixels, and thus interference patterns due to diffraction of light reflected from each subpixel may increase.

However, the display device 30 according to an embodiment of the present disclosure may have a double image reduction effect comparable to that of a low-resolution display device by causing at least some of the reflected lights that generate an interference pattern to have a predetermined phase difference. In an embodiment interference patterns may be caused by light reflected from subpixels of the same color, for example, light reflected from the green subpixels Pg, light reflected from the red subpixels Pr, or light reflected from the blue subpixels Pb. In addition, subpixels of the same color that generate interference patterns may be positioned adjacent to each other. The display device 30 of an embodiment of the present disclosure may include a phase difference pattern structure such that at least some of the light reflected from the same color subpixels has a predetermined phase difference. In the following description, without any further explanation, the term phase difference may mean a phase difference between the lights reflected from subpixels of the same color as described above.

Referring to the subpixel array structure of FIG. 6, in an embodiment, at least some of the light reflected from each of the four green subpixels Pg arranged at each corner of the virtual quadrangle VSG centered around one red subpixel Pr may have different phases from each other. At least some of the light reflected from each of the four blue subpixels Pb arranged at each corner of the virtual quadrangle VSB centered around one red subpixel Pr may have different phases from each other. In addition, at least some of the light reflected from each of the four red subpixels Pr arranged at each corner of the virtual quadrangle VSR centered around one blue subpixel Pb may have different phases from each other.

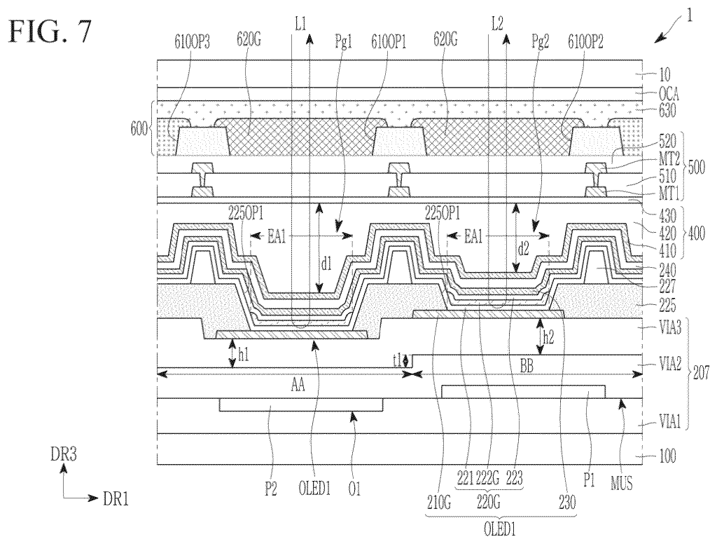

FIG. 7 is a schematic cross-sectional view of the display device according to an embodiment. Referring to FIG. 7, a phase difference pattern structure according to an embodiment will be described in detail. Hereinafter, a phase difference pattern structure will be described with reference to the green subpixel Pg, but the same structure may be applied to the red subpixel Pr and the blue subpixel Pb, and any description that overlaps with the previous description is omitted for economy of explanation.

Referring to FIG. 4 and FIG. 7, a plurality of subpixels of the display device 30 according to an embodiment may include a 1-1 subpixel Pg1 and a 1-2 subpixel Pg2 emitting light of the same color. In an embodiment, the plurality of subpixels of the display device 30 may include a first green subpixel and a second green subpixel. The 1-1 subpixel Pg1 and the 1-2 subpixel Pg2 may be positioned adjacent to each other (e.g., in the first direction DR1). In an embodiment, the 1-1 subpixel Pg1 may be referred to as the first green subpixel, and the 1-2 subpixel Pg2 may be referred to as the second green subpixel.

Each of the 1-1 subpixel Pg1 and the 1-2 subpixel Pg2 may include a subpixel electrode 210G, an intermediate layer 220G, and an opposed electrode 230 constituting the first organic light emitting diode OLED1. The light reflected from each subpixel may be light reflected by the metal layer of each subpixel, for example, the subpixel electrode 210G or the opposed electrode 230 (e.g., opposite electrode). For example, a first light L1 may be light reflected from the subpixel electrode of the 1-1 subpixel. A second light L2 may be light reflected from the subpixel electrode of the 1-2 subpixel.

Referring to FIG. 4 and FIG. 7, a first insulation layer VIA1 and a second insulation layer VIA2 may be disposed on the thin film transistor TFT that is disposed on the substrate 100.

In an embodiment, the second insulation layer VIA2 may include a first area AA overlapping the 1-1 subpixel Pg1 and a second area BB overlapping the 1-2 subpixel Pg2. Each of the first area AA and the second area BB may be an area that overlaps the light emitting areas EA1, EA2, and EA3 of the corresponding subpixel.

In an embodiment, the 1-2 subpixel Pg2 may include a first pattern P1, and the first pattern P1 may be disposed between the first insulation layer VIA1 and the second area BB (e.g., in the third direction DR3). The first pattern P1 may be disposed on the first insulation layer VIA1. For example, a lower surface of the first pattern P1 may directly contact an upper surface of the first insulation layer VIA1 and side surfaces and an upper surface of the first pattern P1 may directly contact the second insulation layer VIA2. In an embodiment, the first pattern P1 may correspond to a source electrode and a drain electrode of the thin film transistor TFT. The source electrode and drain electrode may be connected to a source region and a drain region of a semiconductor layer, respectively, through openings formed in the first insulation layer VIA1.

In an embodiment, the 1-1 subpixel Pg1 may include a second pattern P2, and the second pattern P2 may be disposed between the first insulation layer VIA1 and the first area AA (e.g., in the third direction DR3). The second pattern P2 may be disposed below the second insulation layer VIA2. For example, in an embodiment, an upper surface of the second pattern P2 may directly contact a lower surface of the second insulation layer VIA2 and side surfaces and a bottom surface of the second pattern P2 may directly contact the first via insulation layer VIA1. In an embodiment, the second pattern P2 may correspond to a source electrode and a drain electrode of the thin film transistor TFT. The source electrode and drain electrode may be connected to the source region and the drain region of the semiconductor layer, respectively, through the openings formed in the first insulation layer VIA1.

The first insulation layer VIA1 may include a first recess portion O1 that overlaps the second pattern P2 in the third direction DR3. An upper surface of the first insulation layer VIA1, excluding the first recess portion O1, is called a main upper surface MUS. At least a portion of the second pattern P2 may be disposed inside the first recess portion O1. For example, at least a portion of the source electrode and the drain electrode of the thin film transistor TFT may be embedded within the first recess portion O1 of the first insulation layer VIA1.

According to an embodiment, a first step t1 exists between an upper surface of the first area AA of the first insulation layer VIA1 and an upper surface of the second area BB. The second pattern P2 according to an embodiment is disposed inside the first recess portion O1 of the first insulation layer VIA1, but the first pattern P1 may be disposed on (e.g., disposed directly above in the third direction DR3) the main upper surface MUS of the first insulation layer VIA1 such that the first step t1 can be formed. In an embodiment, the first step t1 may be less than or equal to a depth of the first recess portion O1 in the third direction DR3. For example, in an embodiment a thickness of the first pattern P1 and a thickness of the second pattern P2 may be the same as each other in the third direction DR3. In an embodiment, the thickness of the first insulation layer VIA1 in the first area AA and second area BB may be constant within 10%.

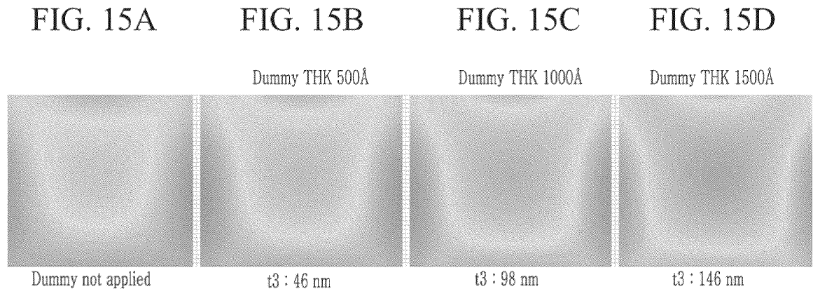

A phase difference may occur between the first light L1 and the second light L2 due to the first step t1. For example, in the case of the first light L1, the first light L1 may have an additional path of t1+t1*cos θ (θ=reflection angle, as shown in FIG. 15) due to the first step t1 compared to the second light L2. The first light L1 may have a phase difference of the additional path compared to the second light L2. The phase difference may be (t1+t1*cos θ)·n (n=refractive index). The double image reduction effect may be greatest when the phase difference between the first light L1 and the second light L2 is an odd multiple of half the wavelength of the corresponding light.

According to an embodiment, the phase difference between the first light L1 and the second light L2 may correspond to

$$\frac{m}{2} λ 1$$

$$( m = odd number ) .$$

The first step t1 may have a height (e.g., a thickness in the third direction DR3) corresponding to

$$\frac{m}{2 n ( 1 + cos θ )} λ 1 ,$$

$$( m = odd number ) .$$

According to an embodiment, the third insulation layer VIA3 may further be disposed on (e.g., disposed directly thereon) the second insulation layer VIA2. In an embodiment, a thickness h1 of the third insulation layer VIA3 in the third direction DR3 on the upper side of the first area AA may be equal to a thickness h2 of the third insulation layer VIA3 in the third direction DR3 on the upper side of the second area BB within 10%.

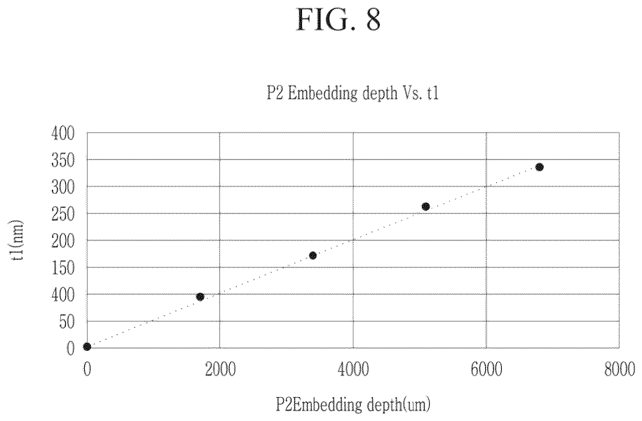

FIG. 8 is a graph that shows a step of the planarization layer 207 according to a pattern embedding depth of the display device according to an embodiment.

Referring to FIG. 8, the depth at which the second pattern P2 is embedded in the first insulation layer VIA1 with the main upper surface MUS of the first insulation layer VIA1 as a reference and the first step t1 may be proportional to the relationship of a linear function. The first step t1 may be proportional to the depth of the first recess portion O1 of the first insulation layer VIA1. According to the graph, when the second pattern P2 is embedded to a depth of about 2000 μm with the main upper surface MUS of the first insulation layer VIA1 as a reference, the first step t1 may have a height (e.g., a thickness in the third direction DR3) of about 400 nm.

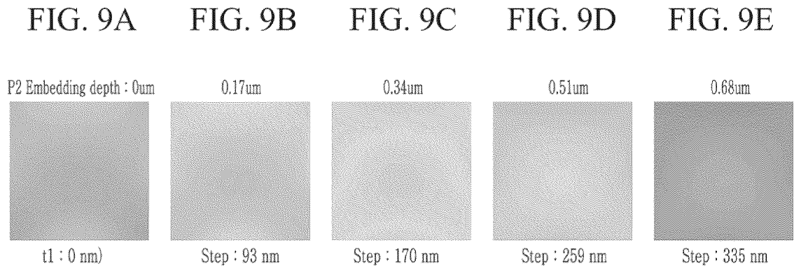

Hereinafter, referring to FIGS. 9A-9E, images of the planarization layer 207 according to the embedded depth of the second pattern P2 from the main upper surface MUS of the first insulation layer VIA1 according to an embodiment will be described. FIGS. 9A-9E are images of the planarization layer 207 according to the pattern embedding depth of the display device according to an embodiment.

Referring to FIGS. 9A-9E, together with FIG. 7, with the upper surface of substrate 100 as a reference, a height of an upper surface of the first pattern P1 may be greater than a height of an upper surface of the second pattern P2. The second pattern P2 may be embedded in the first insulation layer VIA1 and disposed within the first recess portion O1 included in the first insulation layer VIA1. FIGS. 9A-9E are images of the planarization layer 207 including the first area AA according to the depth in which the second pattern P2 is embedded in the first insulation layer VIA1 using the main upper surface MUS of the first insulation layer VIA1 as a reference.

FIG. 9A is an image of the planarization layer 207 in a case in which the second pattern P2 is embedded in the first insulation layer VIA1 with a depth of 0 μm using the main upper surface MUS of the first insulation layer VIA1 as a reference. Since the embedding depth of the second pattern P2 is 0 μm, the first step t1 may also be about 0 nm.

FIG. 9B is an image of the planarization layer 207 when the second pattern P2 is embedded to a depth of 0.17 μm using the upper surface of the first insulation layer VIA1 as a reference. In this case, the second pattern P2 is embedded in the first insulation layer VIA1 and disposed within the first recess portion O1 included in the first insulation layer VIA1, and the first step t1 is formed between the upper surface of the first area AA and the upper surface of the second area BB. When the second pattern P2 is embedded in the first recess portion O1 with a depth of 0.17 μm, the first step t1 may be formed to be approximately 93 nm.

FIG. 9C is an image of the planarization layer 207 when the second pattern P2 is embedded to a depth of 0.34 μm using the upper surface of the first insulation layer VIA1 as a reference. In this case, the first step t1 may be formed to be about 170 nm.

FIG. 9D is an image of the planarization layer 207 when the second pattern P2 is embedded to a depth of 0.51 μm using the upper surface of the first insulation layer VIA1 as a reference. In this case, the first step t1 may be formed to be about 259 nm.

FIG. 9E is an image of the planarization layer 207 when the second pattern P2 is embedded to a depth of 0.68 μm using the upper surface of the first insulation layer VIA1 as a reference. In this case, the first step t1 may be formed to be about 335 nm.

Referring to FIGS. 9A-9E, a portion including the first area AA may have a color that is different from a color of a portion where the second pattern P2 is embedded in the first insulation layer VIA1 and disposed inside the first recess portion O1 included in the first insulation layer VIA1 such that a pattern is not included. FIGS. 9A-9E are examples of images of the planarization layer 207, and may have different colors depending on the embedding depth of the second pattern P2.

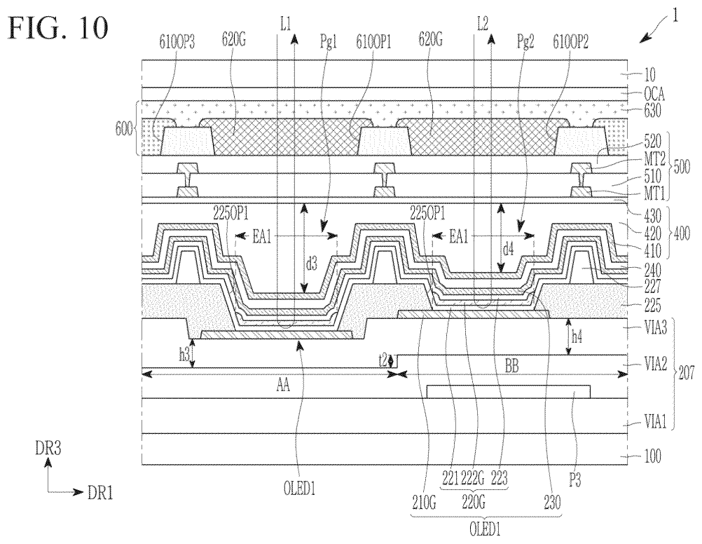

FIG. 10 is a schematic cross-sectional view of the display device according to an embodiment. FIG. 10 may be a cross-sectional view of a display device in a design where the source electrode and the drain electrode of a thin film transistor TFT or a conductive layer SD are avoided to have a phase difference between the reflected light from subpixels of the same color.

Referring to FIG. 10, together with FIG. 4, the plurality of subpixels of the display device 30 may include a 1-1 subpixel Pg1 and a 1-2 subpixel Pg2, each emitting light of the same color. In an embodiment, the plurality of subpixels of the display device 30 may include a first green subpixel and a second green subpixel. The 1-1 subpixel Pg1 and the 1-2 subpixel Pg2 may be positioned adjacent to each other (e.g., in the first direction DR1). In an embodiment, the 1-1 subpixel Pg1 may be referred to as the first green subpixel, and the 1-2 subpixel Pg2 may be referred to as the second green subpixel.

In an embodiment, each of the 1-1 subpixel Pg1 and the 1-2 subpixel Pg2 may include a subpixel electrode 210G, an intermediate layer 220G, and an opposed electrode 230 (e.g., an opposite electrode) forming the first organic light emitting diode OLED1. Light reflected from each subpixel may be light reflected by a metal layer of each subpixel, for example, the subpixel electrode 210G or the opposed electrode 230. For example, the first light L1 may be light reflected from the subpixel electrode of the 1-1 subpixel Pg1. The second light L2 may be light reflected from the subpixel electrode of the 1-2 subpixel Pg2.

Referring to FIG. 4 and FIG. 10, the first insulation layer VIA1 and the second insulation layer VIA2 may be disposed on the thin film transistor TFT that is disposed on the substrate 100.

In an embodiment, the second insulation layer VIA2 may include the first area AA overlapping the 1-1 subpixel Pg1 and the second area BB overlapping the 1-2 subpixel Pg2.

The 1-2 subpixel Pg2 may include a third pattern P3 that overlaps the first light emitting area EA1 of the first organic light emitting diode OLED1. The third pattern P3 may be disposed between the first insulation layer VIA1 and the second area BB (e.g., in the third direction DR3). The third pattern P3 may be disposed in a portion where the first insulation layer overlaps the second area. In an embodiment, the third pattern P3 may be disposed above the first insulation layer VIA1. For example, a bottom surface of the third pattern P3 may be disposed directly on an upper surface of the first insulation layer VIA1 and side surfaces and a top surface of the third pattern P3 may directly contact the second insulation layer VIA2. In an embodiment, at least a portion of the third pattern P3 may correspond to the source electrode and the drain electrode of the thin film transistor TFT on the substrate 100, in which case the source electrode and the drain electrode may be connected to a source region and a drain region of the semiconductor layer, respectively, through an opening formed in the first insulation layer VIA1. Depending on embodiments, the third pattern P3 may be a part of a signal line or voltage line (referred to as a data conductive layer SD) that transmits a signal or voltage to the thin film transistor TFT. For example, the third pattern P3 may correspond to the driving voltage lines transmitting a driving voltage and a part of at least one of the data lines transmitting the data voltage.

In the display device according to an embodiment, a pattern such as the second pattern P2 and the third pattern P3 described above may not exist between the first organic light emitting diode OLED1 of the 1-1 subpixel Pg1 and the first insulation layer VIA1 on the cross-section. For example, the inclusion of the third pattern P3 is designed to avoid overlapping the first light emitting area EA1 of the first organic light emitting diode OLED1 in the 1-1 subpixel Pg1 such that the third pattern P3 does not overlap the first light emitting area EA1 of the 1-1 subpixel Pg1, and the third pattern P3, which is disposed between the first insulation layer VIA1 and the second area BB while overlapping the first organic light emitting diode OLED1 of the 1-2 subpixel Pg2, may be used to generate a second step t2 in the first area AA and the second area BB of the upper surface of the first insulation layer VIA1 to form a phase difference between the first light L1 and the second light L2.

The second step t2 exists between the upper surface of the first area AA and the upper surface of the second area BB of the first insulation layer VIA1. In an embodiment, a thickness of the first insulation layer VIA1 in the first area AA and second area BB may be constant within 10%.

A phase difference may occur between the first light L1 and the second light L2 due to the second step t2. In the case of the first light L1, compared to the second light L2, an additional path of t2+t2*cos θ (0=reflection angle, as shown in FIG. 15) may be formed by the second step t2. The first optical path L1 may have a phase difference of an additional path compared to the second optical path L2. The phase difference may be (t2+t2*cos θ)·n (n=refractive index). The double image reduction effect may be greatest when the phase difference between the first light L1 and the second light L2 is an odd multiple of half the wavelength of the corresponding light.

According to an embodiment, the phase difference between the first light L1 and the second light L2 may correspond to

$$\frac{m}{2} λ 1$$

$$( m = odd number ) .$$

The second step t2 may correspond to

$$\frac{m}{2 n ( 1 + cos θ )} λ 1$$

$$( m = odd number ) .$$

According to an embodiment, the third insulation layer VIA3 may be disposed further on (e.g., disposed directly thereon) the second insulation layer VIA2. In an embodiment, a thickness h3 of the third insulation layer VIA3 in the third direction DR3 above the first area AA may be equal to a thickness h4 of the third insulation layer VIA3 in the third direction DR3 above the second area BB within 10%.

According to an embodiment, the thickness of the third pattern P3 may be about 6800 Å, and in this embodiment, a height of the second step (e.g., thickness in the third direction DR3) may be in a range of about 250 nm to about 270 nm. However, embodiments of the present disclosure are not necessarily limited thereto.

According to an embodiment, the planarity of the plurality of lower openings 225OP may be within 30 nm. For example, in an embodiment the planarity of the planarization layer 207 including the first insulation layer VIA1 and the second insulation layer VIA2 overlapping the first to third light emitting areas EA1, EA2, and EA3 may be within 30 nm. Planarity may mean a difference between the smallest height and the largest height of the upper surface of the planarization layer 207, with the lower surface of the planarization layer 207 as a reference in the same light emitting area EA.

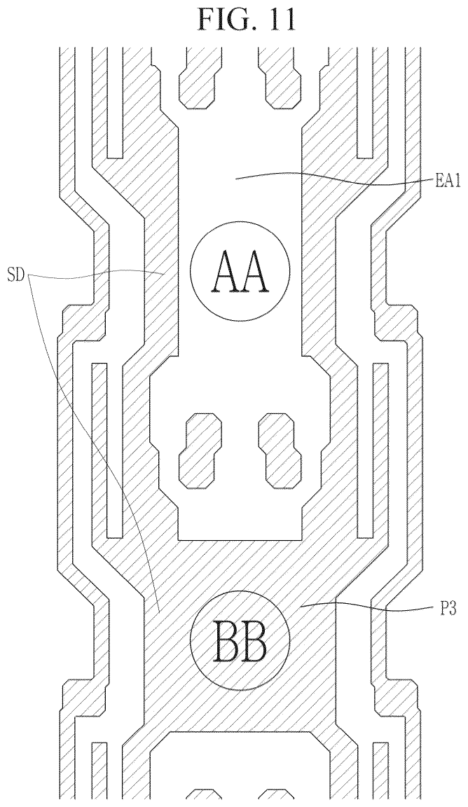

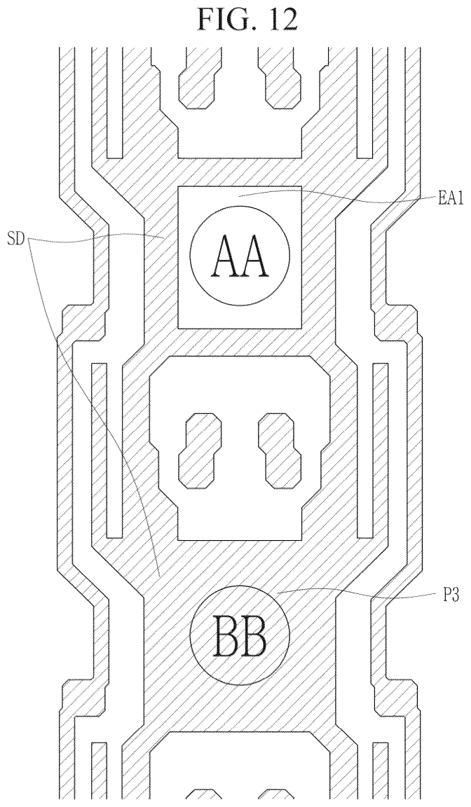

FIG. 11 and FIG. 12 are top plan views of the conductive layer SD according to an embodiment.

Specifically, FIG. 11 and FIG. 12 illustrate examples of the planar shape of the data conductive layer SD disposed in regions corresponding to the plurality of subpixels adjacent in the horizontal and vertical directions. Here, the horizontal direction may correspond to the first direction DR1 described above, and the vertical direction may correspond to the second direction DR2. In the examples shown in FIG. 11 and FIG. 12, the data conductive layers SD corresponding to the columns of two subpixels adjacent in the horizontal direction may have a shape that is symmetrical in the horizontal direction.

Referring to FIG. 11 and FIG. 12, the third pattern P3 of the data conductive layer SD exists in a part where the second area BB of the first insulation layer VIA1 is disposed, but a data conductive layer SD such as the third pattern P3 may not exist in a part where the first area AA is disposed. This is because the data conductive layer SD in the first area AA may be designed to avoid being separated from the first light emitting area EA1 such that the data conductive layer SD does not overlap the first light emitting area EA1 of the 1-1 subpixel Pg1. For example, the data conductive layer SD may be disposed in a part that does not overlap the first light emitting area EA1 of the 1-1 subpixel Pg1. The data conductive layer SD may include a portion facing the first light emitting area EA1 of the 1-1 subpixel Pg1 with a space therebetween that overlaps the first light emitting area EA1.

Referring to FIG. 12, similar to FIG. 11, a data conductive layer SD such as the third pattern P3 may exist in a part where the second area BB is disposed. On the other hand, the data conductive layer SD may not exist in a part where the first area AA is disposed and overlaps the first light emitting area EA1. This is because that the data conductive layer SD is designed to avoid overlapping the first light emitting area EA1, and thus the data conductive layer SD is disposed in a part that does not overlap the first light emitting area EA1 of the 1-1 subpixel Pg1. In a region corresponding to the first area AA, the data conductive layer SD surrounds an empty space that overlaps the first light emitting area EA1 of the 1-1 subpixel Pg1, and thus the data conductive layer SD may not overlap the first light emitting area EA1 of the 1-1 subpixel Pg1.

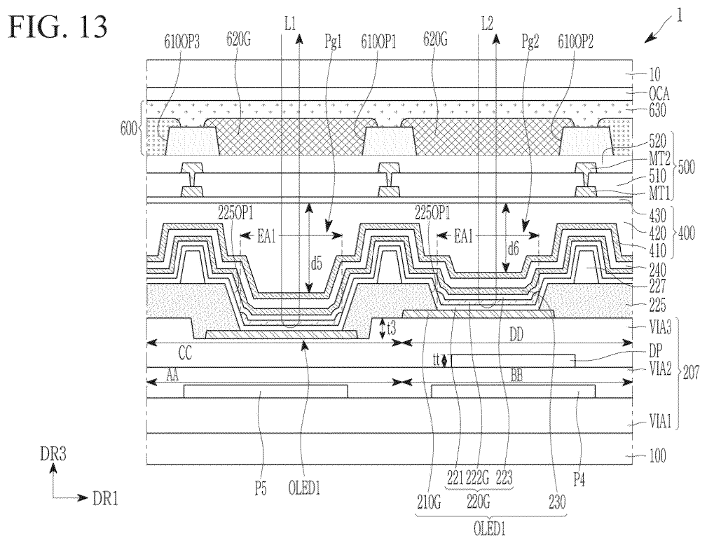

FIG. 13 is a schematic cross-sectional view of the display device according to an embodiment. Referring to FIG. 13, a phase difference pattern structure according to an embodiment will be described in detail.

Referring to FIG. 4 and FIG. 13, the plurality of subpixels of the display device 30 may include a 1-1 subpixel Pg1 and a 1-2 subpixel Pg2 that emit light of the same color as each other. In an embodiment, the plurality of subpixels of the display device 30 may include a first green subpixel and a second green subpixel. The 1-1 subpixel Pg1 and the 1-2 subpixel Pg2 may be positioned adjacent to each other (e.g., in the first direction DR1). In an embodiment, the 1-1 subpixel Pg1 may be referred to as the first green subpixel, and the 1-2 subpixel Pg2 may be referred to as the second green subpixel.

Each of the 1-1 subpixel Pg1 and the 1-2 subpixel Pg2 may include a subpixel electrode 210G, an intermediate layer 220G, and an opposed electrode 230 (e.g., an opposite electrode) constituting the first organic light emitting diode OLED1. The light reflected from each subpixel may be light reflected by the metal layer of each subpixel, for example, the subpixel electrode 210G or the opposed electrode 230. For example, a first light L1 may be light reflected from the subpixel electrode of the 1-1 subpixel. A second light L2 may be light reflected from the subpixel electrode of the 1-2 subpixel.

Referring to FIG. 13, a first insulation layer VIA1 and a second insulation layer VIA2 may be disposed on the substrate 100. A third insulation layer VIA3 may be disposed on (e.g., disposed directly thereon) the second insulation layer VIA2.

The second insulation layer VIA2 may include a first area AA overlapping the 1-1 subpixel Pg1 and a second area BB overlapping the 1-2 subpixel Pg2.

In an embodiment, the 1-2 subpixel Pg2 may include a fourth pattern P4, and the fourth pattern P4 may be disposed between the first insulation layer VIA1 and the second area BB (e.g., in the third direction DR3). The fourth pattern P4 may be disposed above the first insulation layer VIA1. For example, a lower surface of the fourth pattern P4 may directly contact an upper surface of the first insulation layer VIA1 and side surfaces and a top surface of the fourth pattern P4 may directly contact the second insulation layer VIA2. The fourth pattern P4 may be identical to the first pattern P1 described above. However, embodiments of the present disclosure are not necessarily limited thereto.

In an embodiment, the 1-1 subpixel Pg1 may include a fifth pattern P5, and the fifth pattern P5 may be disposed between the first insulation layer VIA1 and the first area AA (e.g., in the third direction DR3). The fifth pattern P5 may be disposed above the first insulation layer VIA1. For example, a lower surface of the fifth pattern P5 may directly contact an upper surface of the first insulation layer VIA1 and side surfaces and a top surface of the fifth pattern P5 may directly contact the second insulation layer VIA2. The fifth pattern P5 may be identical to the second pattern P2 described above. However, embodiments of the present disclosure are not necessarily limited thereto.

In an embodiment, the fourth pattern P4 and the fifth pattern P5 may correspond to the source electrode and the drain electrode of the thin film transistor TFT. The source electrode and drain electrode may be connected to a source region and a drain region of a semiconductor layer, respectively, through openings formed in the first insulation layer VIA1.

The third insulation layer VIA3 may include a third area CC disposed at the 1-1 subpixel Pg1 and overlapping the first area AA, and a fourth area DD disposed at the 1-2 subpixel Pg2 and overlapping the second area BB.

A dummy pattern DP may be disposed between the second insulation layer VIA2 and the fourth area DD. The dummy pattern DP may be disposed below the first organic light emitting diode OLED1 of the 1-2 subpixel Pg2 and above the second insulation layer VIA2. For example, a lower surface of the dummy pattern DP may directly contact an upper surface of the second insulation layer VIA2 and side surfaces and a top surface of the dummy pattern DP may directly contact the third insulation layer VIA3. The dummy pattern DP may be a pattern that does not perform a separate function. However, embodiments of the present disclosure are not necessarily limited thereto. The dummy pattern DP may be an island-shaped pattern formed limited to the 1-2 subpixels Pg2. In the third area CC, there may not be a pattern of the same layer as the dummy pattern DP.

A third step t3 may exist between an upper surface of the third area CC VIA3 and an upper surface of the fourth area DD of the third insulation layer. The third step t3 may be formed by a thickness tt of the dummy pattern DP disposed between the second insulation layer VIA2 and the fourth area DD.

A phase difference may occur between the first light L1 and the second light L2 due to the third step t3. In the case of the first light L1, the first light L1 may have an additional path of t3+t3*cos θ (θ=reflection angle, as shown in FIG. 15) due to the third step t3. The light L1 may have a phase difference of the additional path compared to the second optical path L2. The phase difference may be (t3+t3*cos θ)·n (n=refractive index). The double image reduction effect may be greatest when the phase difference between the first light L1 and the second light L2 is an odd multiple of half the wavelength of the corresponding light.

According to an embodiment, the phase difference may correspond to

$$\frac{m}{2} λ 1$$

$$( m = odd number ) .$$

The second step t2 may correspond to

$$\frac{m}{2 n ( 1 + cos θ )} λ 1$$

$$( m = odd number ) .$$

According to an embodiment, the thickness tt of the dummy pattern DP may be about 1000 Å, and in this embodiment, the third step t3 may be in a range of about 85 nm to about 100 nm. However, embodiments of the present disclosure are not necessarily limited thereto.

According to an embodiment, the planarity of the plurality of lower openings 225OP may be within 30 nm. For example, the planarity of the planarization layer 207 including the first insulation layer VIA1 and the second insulation layer VIA2 overlapping the first to third light emitting areas EA1, EA2, and EA3 may be within 30 nm. Planarity may mean a difference between the smallest height and the largest height of the upper surface of the planarization layer 207, with the lower surface of the planarization layer 207 as a reference in the same light emitting area EA.

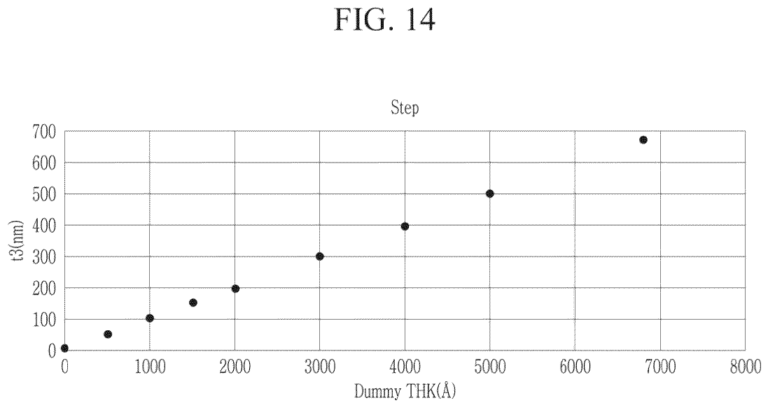

FIG. 14 is a graph that shows a step of the planarization layer 207 according to the thickness tt of the dummy pattern DP of the display device according to an embodiment. In FIG. 14, the dummy pattern DP is represented as Dummy, and the thickness tt of the dummy pattern DP is represented as THK.

Referring to FIG. 13 and FIG. 14, the thickness tt of the dummy pattern DP and the third step t3 may be proportional to each other. The third step t3 according to the thickness tt of the dummy pattern DP may be proportional according to a work function. According to the graph, when the thickness tt of the dummy pattern DP is about 1000 Å, the third step t3 has a value of about 100 nm.

Hereinafter, referring to FIG. 15, the profile of the planarization layer 207 will be described. FIG. 15A to FIG. 15D are images of the profile of the planarization layer 207 including the fourth area DD according to the thickness of the dummy pattern DP. In FIG. 14, the dummy pattern DP is represented as Dummy, and the thickness tt of the dummy pattern DP is represented as THK.

FIG. 15A is a profile image of the planarization layer 207 including the fourth area DD when the dummy pattern DP is not applied.

FIG. 15B is a profile image of the planarization layer 207 including the fourth area DD when the thickness of the dummy pattern DP is 500 Å. The dummy pattern DP is disposed on the second insulation layer VIA2 and thus the third step t3 is formed between the upper surface of the third area CC and the upper surface of the fourth area DD. When the thickness of the dummy pattern DP is 500 Å, the third step t3 may be formed as much as 46 nm.

FIG. 15C is a profile image of the planarization layer 207 including the fourth area DD when the thickness of the dummy pattern DP is 1000 Å. The dummy pattern DP is disposed on the second insulation layer VIA2, and thus the third step t3 is formed between the upper surface of the third area CC and the upper surface of the fourth area DD. When the thickness of the dummy pattern DP is 1000 Å, the third step t3 may be formed as much as 98 nm.

FIG. 15D is a profile image of the planarization layer 207 including the fourth area DD when the thickness of the dummy pattern DP is 1500 Å. The dummy pattern DP is disposed on the second insulation layer VIA2, and the third step t3 is formed between the upper surface of the third area CC and the upper surface of the fourth area DD. When the thickness of the dummy pattern DP is 1500 Å, the third step t3 may be formed as much as 146 nm.

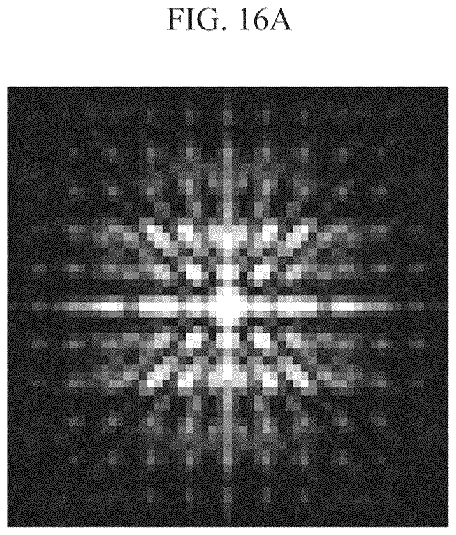

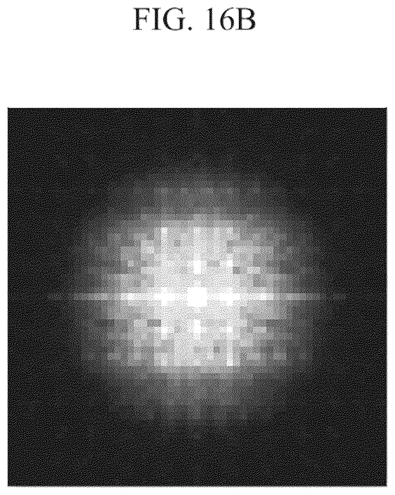

Hereinafter, the principle of reducing the double image by using a phase difference will be described with reference to FIG. 16 to FIG. 19.

FIG. 16A and FIG. 16B are images showing peaks on the point diffusion function of light diffraction at a pixel.

The diffraction patterns of light from each pixel of the display device form a peak in a point diffusion function (PSF) through destructive interference and constructive interference. The larger the interval between each peak on the point diffusion function, the more prominent the double image phenomenon becomes. FIG. 16A is an image of a case where a gap between peaks in the point diffusion function is large and the double image stands out, and FIG. 16B is an image in which the gap between peaks in the point diffusion function is small and double images are reduced.

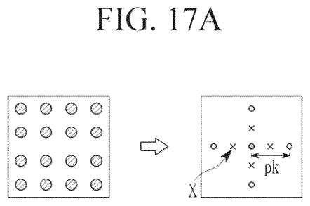

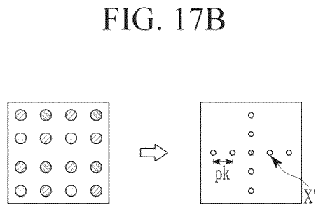

FIG. 17A and FIG. 17B are drawings illustrating the effects of destructive interference and constructive interference on the peak of the point diffusion function of light.

According to FIG. 17A, when all reflected light has the same phase, destructive interference occurs between reflected light at position X. This causes no peak to exist at position X, which in turn increases the gap pk between peaks, which may cause double images to stand out (e.g., be easily seen by the user).

On the other hand, when using reflected light with an appropriate phase difference, constructive interference may occur at position X′. According to FIG. 17B, constructive interference occurs at position X′, and thus a peak may also exist at the position X′. The position where the reinforcing interference occurs may be dispersed. The empty space between peaks may be filled by appropriately arranging the phase difference in this way. The empty space between peaks is reduced, narrowing the gap pk between peaks, which can produce a double-image reduction effect.

According to an embodiment, a high-resolution display device may have a double-image reduction effect comparable to that of a low-resolution display device by causing at least some of the reflected lights that generate an interference pattern to have a predetermined phase difference. By using the first step t1, second step t2, or third step t3 described above, the reflected light may have an additional path due to the steps, and thus at least some of the reflected light has a predetermined phase difference.

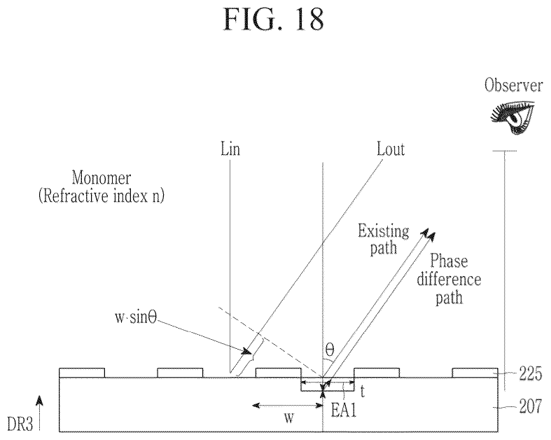

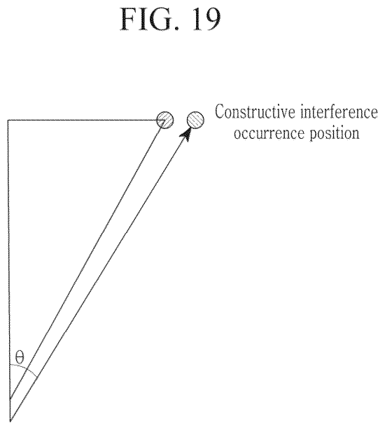

FIG. 18 and FIG. 19 provided to describe the principle of reducing the double image by using a phase difference.

Referring to FIG. 18, it may be assumed that an incident light Lin is incident in a direction perpendicular to the flat upper surface of the second insulation layer VIA2 or third insulation layer VIA3 described above (e.g., third direction DR3). The incident light Lin may be reflected from the top of the planarization layer 207 between the partition walls 225. For example, the incident light Lin may be reflected from the subpixel electrodes included in each subpixel, and may be reflected from the first to third light emitting areas EA1, EA2, and EA3. The equation for a phase of reflected light Lout along the existing path is as follows.

$$w \cdot sin θ \cdot n$$

$$( n = refractive index , θ = reflection angle )$$

In the case of a display device that applies a step t of the upper surface of the second insulation layer VIA2 or third insulation layer VIA3, such as the first step t1, the second step t2, or the third step t3 according to the embodiment, the reflected light Lout may have the following additional path.

$$t + t cos θ$$

$$( θ = reflection angle )$$

Due to such an additional path, the reflected light Lout of the display device to which the step t is applied may have a phase difference of (t+t cos θ)·n compared to the reflected light Lout according to the existing path. Some of the reflected light Lout has a phase difference, which can disperse the positions where constructive interference of the reflected light occurs.

In an embodiment, the step t may be formed by having a source electrode and a drain electrode embedded in the first insulation layer in a portion, or by having a source electrode and a drain electrode disposed outside the light emitting area, or by having a dummy pattern disposed between the second insulation layer and the third insulation layer at a portion.

Referring to FIG. 19, in the case of the phase difference path, the reflected light Lout has a phase difference of (t+t cos θ)·n compared to the reflected light Lout according to the existing path due to the additional path, and the constructive interference may occur at the position of the right circle. As described above, the phase difference between the first light L1 and the second light L2 may reduce the double image by dispersing the positions where the constructive interference of the reflected lights Lout occurs. When the phase difference between the first light L1 and the second light L2 is an odd multiple of half the wavelength of the incident light Lin, the reduction effect of the double image can be significant. When the phase difference between the first light L1 and the second light L2 is an even multiple of half the wavelength of the incident light Lin, they will eventually have the same phase, and therefore no double image reduction effect may be obtained.

Interference patterns may be caused by the light reflected Lout from the subpixels of the same color, for example, a light Lout reflected from the green subpixel, a light Lout reflected from the red subpixel, or a light Lout reflected from a blue subpixel. Additionally, the subpixels of the same color that generate interference patterns may be positioned adjacent to each other. The display device according to an embodiment may include a phase difference pattern structure such that at least some of the light reflected from such subpixels of the same color has a predetermined phase difference.

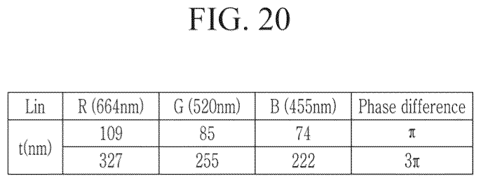

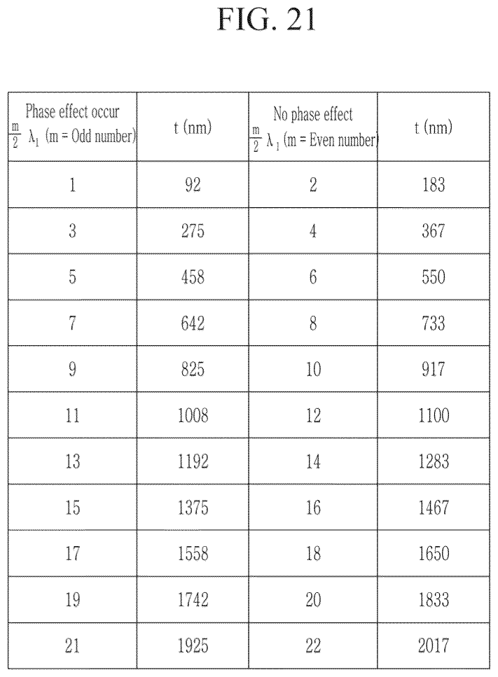

Referring to FIG. 20 and FIG. 21, a step of the planarization layer that can reduce the double image will be described.

FIG. 20 is a table that shows the most suitable step t for reducing double images according to the wavelengths of red light R, green light G, and blue light B. In an embodiment, the first subpixel may be a green subpixel and may display green light G, the second subpixel may be a blue subpixel and may display blue light B, and the third subpixel may be a red subpixel and may display red light R. For the red light R, the step was measured using the wavelength corresponding to 664 nm as a reference. For the green light G, the step was measured using the wavelength corresponding to 520 nm as a reference. For the blue light B, the step was measured using the wavelength corresponding to 455 nm as a reference.

The step t required to make the phase difference 0.5λ₁, which is half the wavelength τ, is 109 nm for the red light R, 85 nm for the green light, and 74 nm for the blue light B.

The step t required to make the phase difference of 1.5λ₁, which is three times half the wavelength, 3τ, is 327 nm for the red light R, 255 nm for the green light, and 222 nm for the blue light B.

FIG. 21 is a table that shows the most suitable step t measured to reduce double images when the average wavelength of the green light G is 550 nm as a reference. When the phase difference between the first light L1 and the second light L2 is an odd multiple of half the wavelength, the reduction effect of the double image is the greatest, and when the phase difference is an even multiple of half the wavelength, the reduction effect of the double image may not be present due to the same phase.

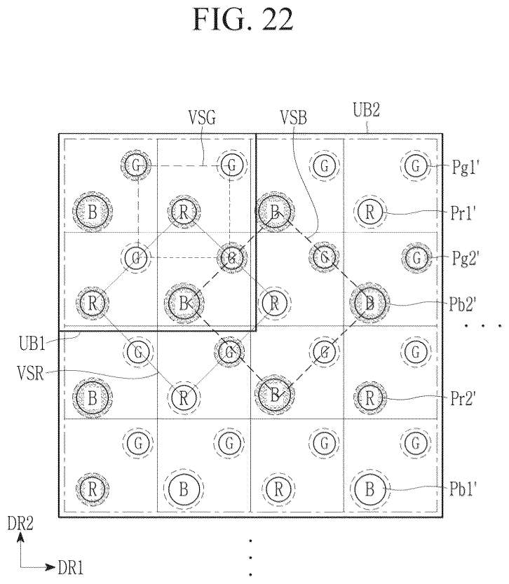

FIG. 22 is a top plan view that illustrates a part of the display device according to an embodiment. FIG. 19 is an example drawing, which shows that light reflected from each of the plurality of subpixels is designed to have a phase difference by using the phase difference pattern structure described above with reference to FIG. 6, FIGS. 9A-9E, and FIG. 12.

Referring to FIG. 22, for example, with reference to light reflected from a first red subpixel Pr1′ as a reference, light reflected from a second red subpixel Pr2′ may have a phase difference of an odd multiple of half a wavelength. With reference to light reflected from a first blue subpixel Pb1′, light reflected from a second blue subpixel Pb2′ may have a phase difference of an odd multiple of half a wavelength. With reference to light reflected from a first green subpixel Pg1′, light reflected from a second green subpixel Pg2′ may have a phase difference of an odd multiple of half a wavelength.

At least some of the light reflected from each of the four green subpixels located at each corner of the virtual quadrangle VSG may have a phase difference of τ. At least some of the light reflected from each of the four blue subpixels located at each corner of the virtual quadrangle VSB may have a phase difference of τ. In addition, at least some of the light reflected from each of the four red subpixels Pr located at each corner of the virtual quadrangle VSR may have a phase difference of τ.

According to the present embodiment, by differently controlling the phase difference of light reflected at each position of subpixels among subpixels of the same color using a phase difference pattern structure, an interference pattern generated by light reflected from subpixels of the same color can be reduced. The phase difference pattern may be designed in an optimized form that can minimize interference patterns.

A phase difference pattern structure corresponding to the plurality of subpixels included in the display device may include an iterative array structure of phase difference pattern unit blocks UB2. The phase difference pattern unit blocks UB2 are virtual unit blocks having a predetermined area including a phase difference pattern structure corresponding to red subpixels, blue subpixels, and green subpixels, respectively, and may be understood as corresponding to the minimum repeating unit of the arrangement pattern of the phase difference pattern structure provided in the display device. In an embodiment, the phase difference pattern unit block UB2 may be a quadrangle. For example, the phase difference pattern unit block UB2 may be a square. The size of the phase difference pattern unit blocks UB2 may be larger than the size of a subpixel pattern unit block UB1. In an embodiment, the subpixels corresponding to the phase difference pattern unit block UB2 may have a structure in which K (K is a natural number) subpixel pattern unit blocks are arranged along the first direction (e.g., DR2 direction) and K (K is a natural number) subpixel pattern unit blocks are arranged along the second direction (e.g., DR1 direction) orthogonal to the first direction.

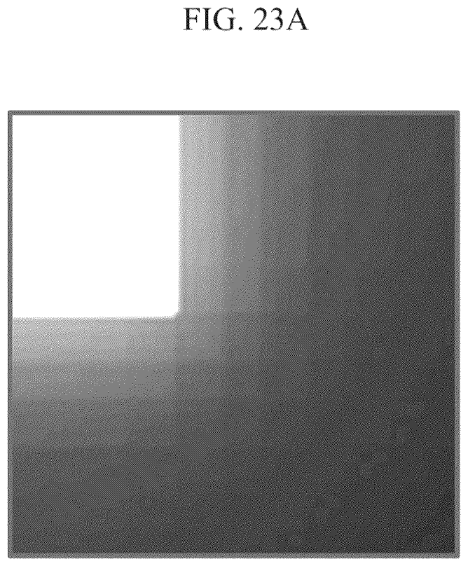

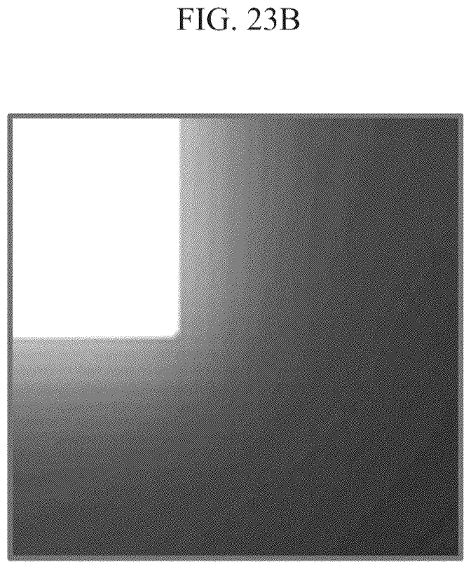

FIG. 23A is a double-image image of a display device according to the comparative example, and FIG. 23B is an image that shows the double image reduction effect of the display device according to an embodiment.

When a plurality of reflected lights have the same phase, destructive interference occurs between wavelengths, thereby causing occurrence of a double image as shown in FIG. 23A according to the comparative example.

When the plurality of reflected lights have a phase difference according to the embodiment, it may be confirmed that the positions where constructive interference occurs between wavelengths are dispersed and the double image is reduced as shown in FIG. 23B according to an embodiment.

While the present disclosure has been described in connection with non-limiting embodiments, it is to be understood that embodiments of the present disclosure are not limited to described embodiments. On the contrary, embodiments of the present disclosure cover various modifications and equivalent arrangements included within the spirit and scope of the present disclosure.

What is claimed is:

1. A display device comprising:
a substrate;
a plurality of transistors disposed on the substrate;
a first insulation layer and a second insulation layer sequentially disposed on the plurality of transistors;
a plurality of subpixels that include first subpixels, second subpixels, and third subpixels, each of the plurality of subpixels including a subpixel electrode disposed on the second insulation layer, a light emitting layer disposed on the subpixel electrode, and an opposite electrode disposed on the light emitting layer;
a partition wall that includes a plurality of lower openings defining light emitting areas of the plurality of subpixels;
a light blocking layer that includes a plurality of upper openings disposed on the partition wall and respectively overlapping the plurality of lower openings; and
a first color filter, a second color filter, and a third color filter that are disposed in the plurality of upper openings, respectively,
wherein the first subpixels comprise a 1-1 subpixel and a 1-2 subpixel that emit light of a same color as each other,
the second insulation layer comprises a first area overlapping the 1-1 subpixel and a second area overlapping the 1-2 subpixel, and
a step is positioned between an upper surface of the first area and an upper surface of the second area.

2. The display device of claim 1, wherein:
light reflected from the 1-1 subpixel has a phase difference with light reflected from the 1-2 subpixel, and the phase difference is
$$\frac{m}{2} λ 1 ,$$
wherein m is an odd number.

3. The display device of claim 2, wherein:
a height of the step is
$$\frac{m}{2 n ( 1 + cos θ )} λ 1 ,$$
wherein m is the odd number and n is a refractive index.

4. The display device of claim 1, comprising:
a first pattern disposed below the 1-2 subpixel and disposed between the first insulation layer and the second insulation layer; and
a second pattern disposed below the 1-1 subpixel and disposed between the first insulation layer and the second insulation layer.

5. The display device of claim 4, wherein:
the first insulation layer comprises a first recess portion overlapping the second pattern; and
at least a portion of the second pattern is disposed in the first recess portion.

6. The display device of claim 5, wherein:
a height of an upper surface of the first pattern with respect to an upper surface of the substrate is greater than a height of an upper surface of the second pattern with respect to the upper surface of the substrate.

7. The display device of claim 5, wherein:
a height of the step is proportional to a depth of the first recess portion of the first insulation layer.

8. The display device of claim 4, wherein:
a third insulation layer is disposed on the second insulation layer.

9. The display device of claim 8, wherein:
the third insulation layer has a same thickness in an upper part of the first area and an upper part of the second area.

10. The display device of claim 1, further comprising:
a data conductive layer disposed on the first insulation layer; and
a third pattern of the data conductive layer in a portion where the first insulation layer overlaps the second area.

11. The display device of claim 10, wherein:
a thickness of the third pattern is about 6800 Å.

12. The display device of claim 11, wherein:
a height of the step is in a range of about 250 nm to about 270 nm.

13. The display device of claim 1, wherein:
a planarity of a planarization layer that include the first insulation layer and the second insulation layer overlapping the respective light emitting areas is within 30 nm, wherein the planarity is a difference between a smallest height and a largest height from a bottom surface of the planarization layer to a top surface of the planarization layer.

14. A display device comprising:
a substrate;
a plurality of transistors disposed on the substrate;
a first insulation layer, a second insulation layer, and a third insulation layer that are sequentially disposed on the plurality of transistors;
a plurality of subpixels that include first subpixels, second subpixels, and third subpixels, each of the plurality of subpixels including a subpixel electrode disposed on the second insulation layer, a light emitting layer disposed on the subpixel electrode, and an opposite electrode disposed on the light emitting layer;
a partition wall that includes a plurality of lower openings defining light emitting areas of the plurality of subpixels;
a light blocking layer that includes a plurality of upper openings disposed on the partition wall and respectively overlapping the plurality of lower openings; and
a first color filter, a second color filter, and a third color filter that are disposed in the plurality of upper openings, respectively,
wherein the first subpixels comprise a 1-1 subpixel and a 1-2 subpixel that emit light of a same color as each other,
the second insulation layer comprises a first area overlapping the 1-1 subpixel and a second area overlapping the 1-2 subpixel,
the third insulation layer comprises a third area overlapping the 1-1 subpixel and a fourth area overlapping the 1-2 subpixel, and
a step is positioned between an upper surface of the third area and an upper surface of the fourth area.

15. The display device of claim 14, wherein:
light reflected from the 1-1 subpixel has a phase difference with light reflected from the 1-2 subpixel.

16. The display device of claim 15, wherein:
a fifth pattern is disposed between the first insulation layer and the first area; and
a fourth pattern is disposed between the first insulation layer and the second area.

17. The display device of claim 16, wherein:
a dummy pattern is disposed between the second insulation layer and the fourth area.

18. The display device of claim 17, wherein:
the phase difference is
$$\frac{m}{2} λ 1 ,$$
and a height of the step is
$$\frac{m}{2 n ( 1 + cos θ )} λ 1 ,$$
wherein m is an odd number and n is a refractive index.

19. An electronic device comprising:
a cover window;
a housing combined with the cover window; and
a display device that is disposed in a space defined by the cover window and the housing,
wherein the display device comprises:
a substrate;
a plurality of transistors disposed on the substrate;
a first insulation layer and a second insulation layer sequentially disposed on the plurality of transistors;
a plurality of subpixels that include first subpixels, second subpixels, and third subpixels, each of the plurality of subpixels including a subpixel electrode disposed on the second insulation layer, a light emitting layer disposed on the subpixel electrode, and an opposite electrode disposed on the light emitting layer;
a partition wall that includes a plurality of lower openings defining light emitting areas of the plurality of subpixels;
an encapsulation layer and a touch sensor layer that are disposed on the opposite electrode;
a light blocking layer that includes a plurality of upper openings disposed on the touch sensor layer and respectively overlapping the plurality of lower openings; and
a first color filter, a second color filter, and a third color filter that are disposed in the plurality of upper openings, respectively,
the first subpixels comprise a 1-1 subpixel and a 1-2 subpixel that emit light of a same color as each other,
the second insulation layer comprises a first area overlapping the 1-1 subpixel and a second area overlapping the 1-2 subpixel,
a step is positioned between an upper surface of the first area and an upper surface of the second area, and
a polarizer is not disposed above the touch sensor layer.

20. The electronic device of claim 19, comprising:
a first pattern disposed below the 1-2 subpixel and disposed between the first insulation layer and the second insulation layer; and
a second pattern disposed below the 1-1 subpixel and disposed between the first insulation layer and the second insulation layer.
